(19) United States
(12) Patent Application Publication
(10) Pub. No.: US 2018/0277208 A1
(43) Pub. Date: Sep. 27, 2018

(54) METHODS AND APPARATUS FOR PROGRAMMING BARRIER MODULATED MEMORY CELLS

(71) Applicant: SANDISK TECHNOLOGIES LLC, Plano, TX (US)

(72) Inventors: Deepak Kamalanathan, San Jose, CA (US); Juan P. Saenz, Menlo Park, CA (US); Tanmay Kumar, Pleasanton, CA (US); Emmanuelle Merced-Grafals, San Jose, CA (US); Sebastian J. M. Wicklein, San Jose, CA (US)

(73) Assignee: SANDISK TECHNOLOGIES LLC, Plano, TX (US)

(21) Appl. No.: 15/714,463

(22) Filed: Sep. 25, 2017

Related U.S. Application Data
(60) Provisional application No. 62/477,366, filed on Mar. 27, 2017.

(51) Int. Cl. G11C 13/00; H01L 45/00

(52) U.S. Cl. CPC G11C 13/0069; G11C 13/004; G11C 13/0007; H01L 27/2481; H01L 45/146; G11C 13/0026; G11C 13/0028; H01L 45/1246

(57) ABSTRACT

A memory device is provided that includes a memory controller coupled to a memory cell including a barrier modulated switching structure. The memory controller is adapted to program the memory cell to a first programming state, and program the memory cell to one of a plurality of target programming states from the first programming state.

### PRIORITY CLAIM

This application claims the benefit of U.S. Provisional Patent Application Ser. No. 62/477,366, filed Mar. 27, 2017, which is incorporated by reference herein in its entirety for all purposes.

### BACKGROUND

Semiconductor memory is widely used in various electronic devices such as mobile computing devices, mobile phones, solid-state drives, digital cameras, personal digital assistants, medical electronics, servers, and non-mobile computing devices. Semiconductor memory may include non-volatile memory or volatile memory. A non-volatile memory device allows information to be stored or retained even when the non-volatile memory device is not connected to a power source.

One example of non-volatile memory uses memory cells that include reversible resistance-switching memory elements that may be set to either a low resistance state or a high resistance state. The memory cells may be individually connected between first and second conductors (e.g., a bit line electrode and a word line electrode). The state of such a memory cell is typically changed by proper voltages being placed on the first and second conductors.

In recent years, non-volatile memory devices have been scaled to reduce the cost per bit. However, as process geometries shrink, many design and process challenges are presented

### BRIEF DESCRIPTION OF THE DRAWINGS

FIG. 1A depicts an embodiment of a memory system and a host.

FIG. 1B depicts an embodiment of memory core control circuits.

FIG. 1C depicts an embodiment of a memory core.

FIG. 1D depicts an embodiment of a memory bay.

FIG. 1E depicts an embodiment of a memory block.

FIG. 1F depicts another embodiment of a memory bay.

FIG. 1G depicts another embodiment of a memory block.

FIG. 2A depicts an embodiment of a portion of a monolithic three-dimensional memory array.

FIG. 2B depicts an embodiment of a portion of a monolithic three-dimensional memory array that includes vertical strips of a non-volatile memory material.

FIGS. 3A-3F depict various views of an embodiment monolithic three-dimensional memory array.

FIG. 4 depicts electrical characteristics of an embodiment of a population of memory cells.

FIGS. 5A-5B depict embodiments of programming sequences for programming memory cells.

FIG. 6 depict example current-versus-voltage characteristics of memory cells.

FIG. 7 depict example current-versus-time characteristics of memory cells.

FIGS. 8A-8D are example programming methods for programming BMC memory cells.

FIGS. 9A-9D are diagrams of example programming sequences for sequentially programming BMC memory cells.

FIG. 10 is an example programming sequence for sequentially programming BMC memory cells.

### DETAILED DESCRIPTION

Technology is described for programming memory cells that include a barrier modulated switching structure. In particular, technology is described for programming a memory cell that includes a barrier modulated switching structure to a first programming state, and then programming the memory cell from the first programming state to one of a three or more target programming states. In an embodiment, one or more programming pulses having a first polarity are applied to the memory cell to program the memory cell to the first programming state, and then one or more programming pulses having a second polarity are applied to the memory cell to program the memory cell from the first programming state to one of the target programming states. The second polarity is opposite the first polarity.

Technology also is described for programming a memory cell that includes a barrier modulated switching structure to a first programming state from a first intermediate programming state, and programming the memory cell to a second programming state from a second intermediate programming state. In an embodiment, the first programming state is a lower current state than the second programming state, the first intermediate programming state is a lower current state than the first programming state, and the second intermediate programming state is a higher current state than the second programming state. In another embodiment, the first programming state is a higher current state than the second programming state, the first intermediate programming state is a higher current state than the first programming state, and the second intermediate programming state is a lower current state than the second programming state.

In some embodiments, a memory array may include a cross-point memory array. A cross-point memory array may refer to a memory array in which two-terminal memory cells are placed at the intersections of a first set of control lines (e.g., word lines) arranged in a first direction and a second set of control lines (e.g., bit lines) arranged in a second direction perpendicular to the first direction.

Each two-terminal memory cell may include a reversible resistance-switching memory element disposed between first and second conductors. Example reversible resistance-switching memory elements include a phase change material, a ferroelectric material, a metal oxide (e.g., hafnium oxide), a barrier modulated switching structure, or other similar reversible resistance-switching memory elements.

Example barrier modulated switching structures include a semiconductor material layer (e.g., an amorphous silicon layer) adjacent a conductive oxide material layer (e.g., a titanium oxide layer). Other example barrier modulated switching structures include a thin (e.g., less than about 2 nm) barrier oxide material (e.g., an aluminum oxide layer) disposed between a semiconductor material layer (e.g., an amorphous silicon layer) and a conductive oxide material layer (e.g., a titanium oxide layer).

Still other example barrier modulated switching structures include a barrier oxide material (e.g., an aluminum oxide layer) disposed adjacent a conductive oxide material layer (e.g., a titanium oxide layer), with no semiconductor material layer (e.g., amorphous silicon) in the barrier modulated switching structure. As used herein, a memory cell that includes a barrier modulated switching structure is referred to herein as a “BMC memory cell.”

In some embodiments, each memory cell in a cross-point memory array includes a reversible resistance-switching memory element in series with a steering element or an isolation element, such as a diode, to reduce leakage currents. In other cross-point memory arrays, the memory cells do not include an isolation element.

In an embodiment, a non-volatile storage system may include one or more two-dimensional arrays of non-volatile memory cells. The memory cells within a two-dimensional memory array may form a single layer of memory cells and may be selected via control lines (e.g., word lines and bit lines) in the X and Y directions. In another embodiment, a non-volatile storage system may include one or more monolithic three-dimensional memory arrays in which two or more layers of memory cells may be formed above a single substrate without any intervening substrates.

In some cases, a three-dimensional memory array may include one or more vertical columns of memory cells located above and orthogonal to a substrate. In an example, a non-volatile storage system may include a memory array with vertical bit lines or bit lines that are arranged orthogonal to a semiconductor substrate. The substrate may include a silicon substrate. The memory array may include rewriteable non-volatile memory cells, wherein each memory cell includes a reversible resistance-switching memory element without an isolation element in series with the reversible resistance-switching memory element (e.g., no diode in series with the reversible resistance-switching memory element).

In some embodiments, a non-volatile storage system may include a non-volatile memory that is monolithically formed in one or more physical levels of arrays of memory cells having an active area disposed above a silicon substrate. The non-volatile storage system may also include circuitry associated with the operation of the memory cells (e.g., decoders, state machines, page registers, and/or control circuitry for controlling reading, programming and erasing of the memory cells). The circuitry associated with the operation of the memory cells may be located above the substrate or within the substrate.

In some embodiments, a non-volatile storage system may include a monolithic three-dimensional memory array. The monolithic three-dimensional memory array may include one or more levels of memory cells. Each memory cell within a first level of the one or more levels of memory cells may include an active area that is located above a substrate (e.g., above a single-crystal substrate or a crystalline silicon substrate). In one example, the active area may include a semiconductor junction (e.g., a P-N junction). The active area may include a portion of a source or drain region of a transistor. In another example, the active area may include a channel region of a transistor.

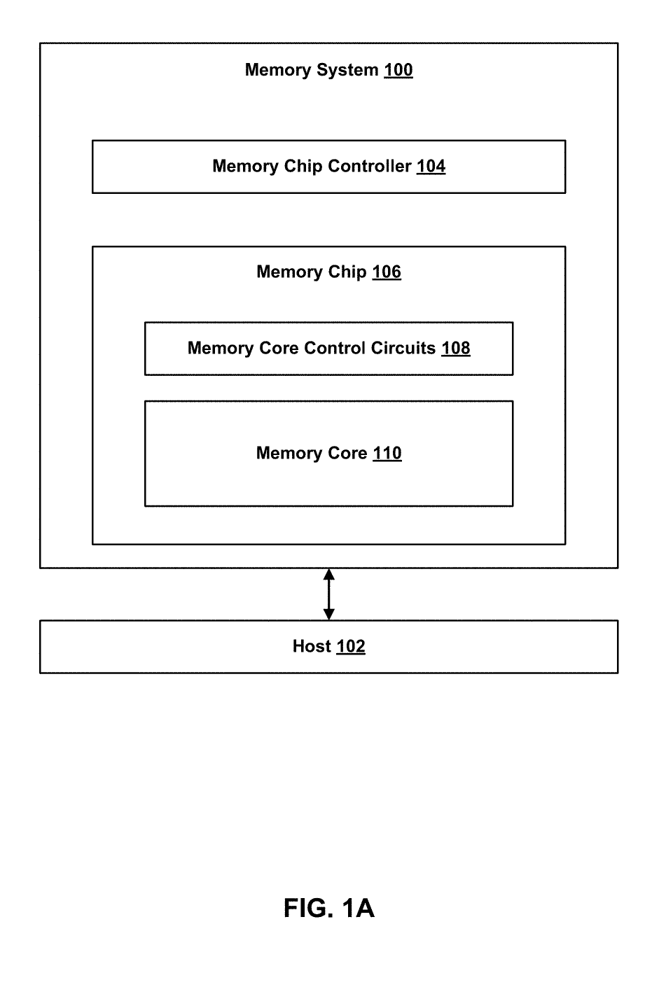

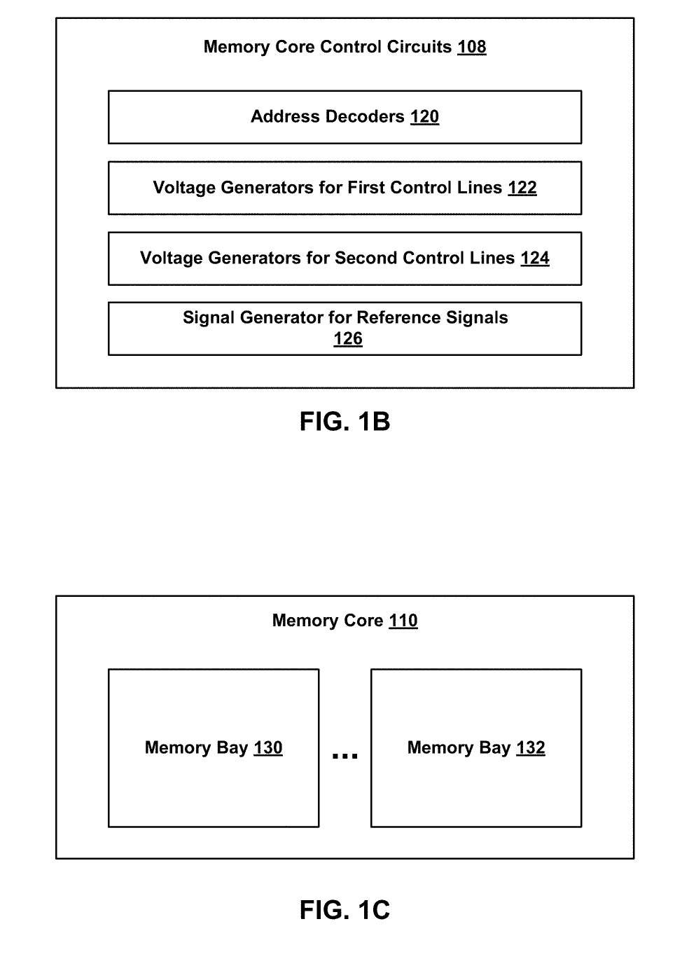

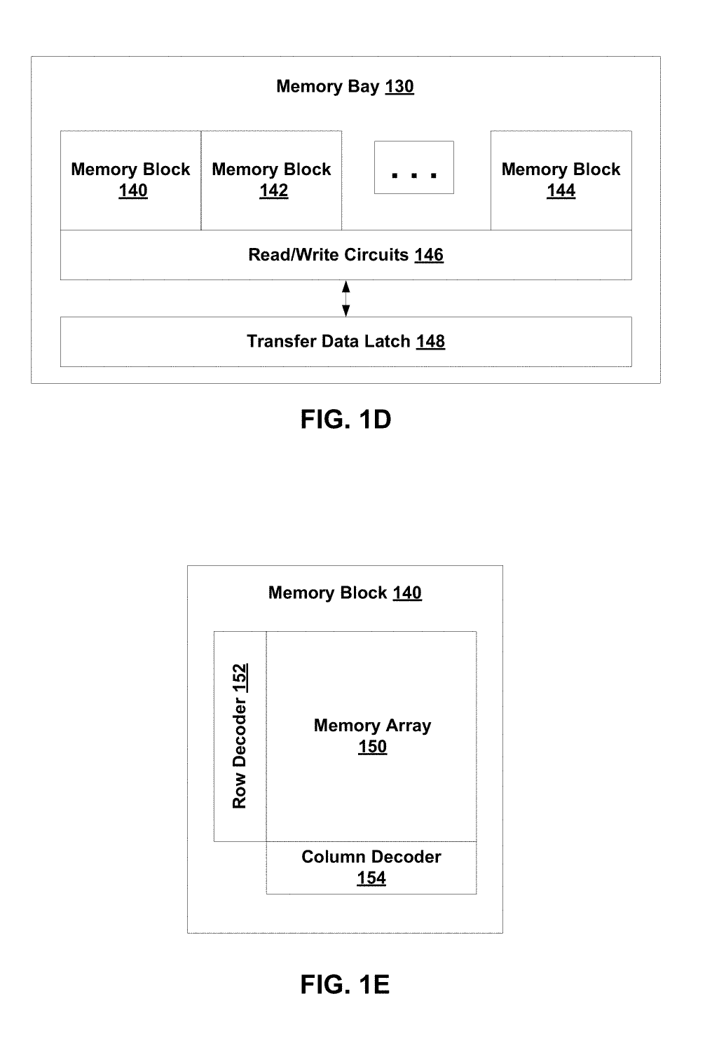

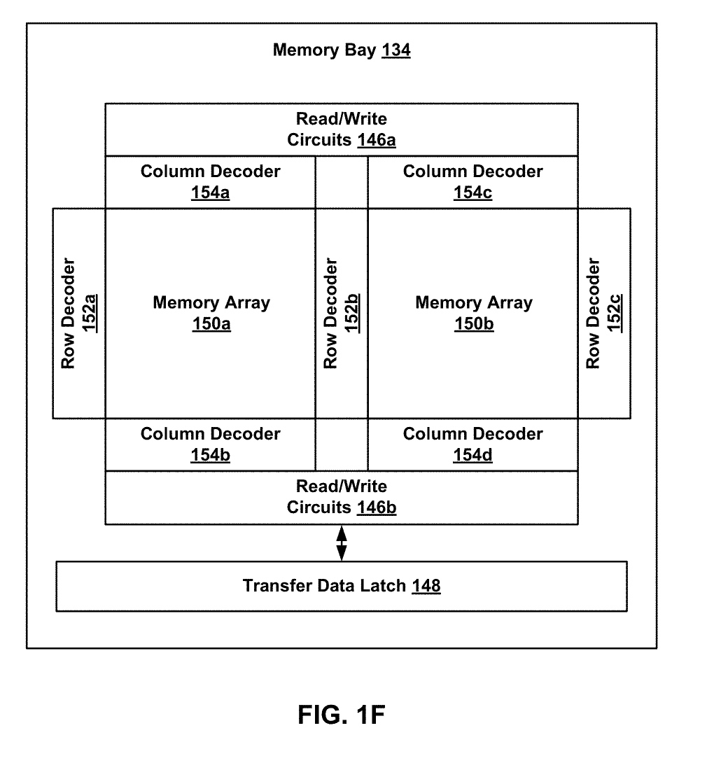

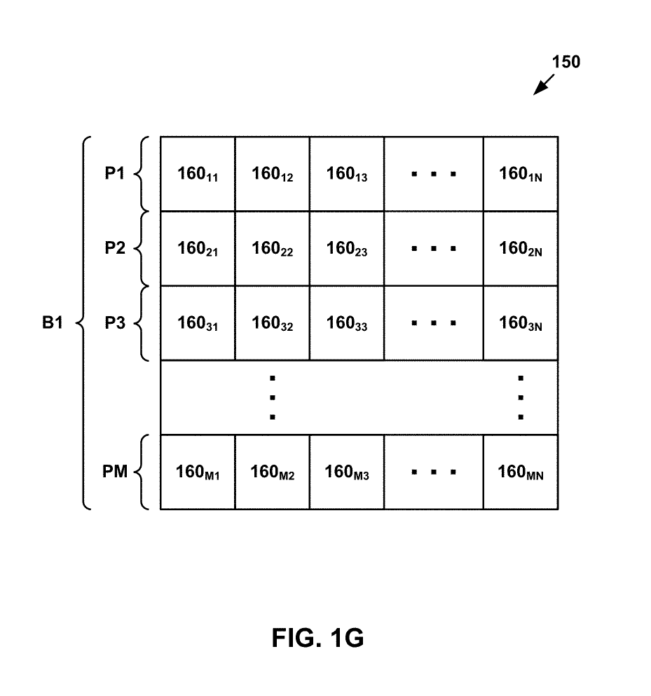

FIG. 1A depicts one embodiment of a memory system 100 and a host 102. Memory system 100 may include a non-volatile storage system interfacing with host 102 (e.g., a mobile computing device). In some cases, memory system 100 may be embedded within host 102. In other cases, memory system 100 may include a memory card. As depicted, memory system 100 includes a memory chip controller 104 and a memory chip 106. Although a single memory chip 106 is depicted, memory system 100 may include more than one memory chip (e.g., four, eight or some other number of memory chips). Memory chip controller 104 may receive data and commands from host 102 and provide memory chip data to host 102.

Memory chip controller 104 may include one or more state machines, page registers, SRAM, and control circuitry for controlling the operation of memory chip 106. The one or more state machines, page registers, SRAM, and control circuitry for controlling the operation of memory chip 106 may be referred to as managing or control circuits. The managing or control circuits may facilitate one or more memory array operations, such as forming, erasing, programming, sand reading operations. In an embodiment, the managing or control circuits may relocate data stored in memory chip 106.

In some embodiments, the managing or control circuits (or a portion of the managing or control circuits) for facilitating one or more memory array operations may be integrated within memory chip 106. Memory chip controller 104 and memory chip 106 may be arranged on a single integrated circuit. In other embodiments, memory chip controller 104 and memory chip 106 may be arranged on different integrated circuits. In some cases, memory chip controller 104 and memory chip 106 may be integrated on a system board, logic board, or a PCB.

Memory chip 106 includes memory core control circuits 108 and a memory core 110. Memory core control circuits 108 may include logic for controlling the selection of memory blocks (or arrays) within memory core 110, controlling the generation of voltage references for biasing a particular memory array into a read or write state, and generating row and column addresses.

Memory core 110 may include one or more two-dimensional arrays of memory cells or one or more three-dimensional arrays of memory cells. In an embodiment, memory core control circuits 108 and memory core 110 are arranged on a single integrated circuit. In other embodiments, memory core control circuits 108 (or a portion of memory core control circuits 108) and memory core 110 may be arranged on different integrated circuits.

A memory operation may be initiated when host 102 sends instructions to memory chip controller 104 indicating that host 102 would like to read data from memory system 100 or write data to memory system 100. In the event of a write (or programming) operation, host 102 will send to memory chip controller 104 both a write command and the data to be written.

The data to be written may be buffered by memory chip controller 104 and error correcting code (ECC) data may be generated corresponding with the data to be written. The ECC data, which allows data errors that occur during transmission or storage to be detected and/or corrected, may be written to memory core 110 or stored in non-volatile memory within memory chip controller 104. In an embodiment, the ECC data are generated and data errors are corrected by circuitry within memory chip controller 104.

Memory chip controller 104 controls operation of memory chip 106. In one example, before issuing a write operation to memory chip 106, memory chip controller 104 may check a status register to make sure that memory chip 106 is able to accept the data to be written. In another example, before issuing a read operation to memory chip 106, memory chip controller 104 may pre-read overhead information associated with the data to be read.

The overhead information may include ECC data associated with the data to be read or a redirection pointer to a new memory location within memory chip 106 in which to read the data requested. Once a read or write operation is initiated by memory chip controller 104, memory core control circuits 108 may generate the appropriate bias voltages for word lines and bit lines within memory core 110, and generate the appropriate memory block, row, and column addresses.

In an embodiment, memory chip controller 104 includes one or more managing or control circuits that control operation of a memory array in memory chip 106. In an embodiment, the one or more managing or control circuits provide control signals to a memory array to perform an erase operation, a read operation, and/or a write operation on the memory array. In an embodiment, in response to detecting one or more conditions, the one or more managing or control circuits relocate stored data between different portions of memory core 110.

In an embodiment, the one or more managing or control circuits include any one of or a combination of control circuitry, state machine, decoders, sense amplifiers, read/write circuits, and/or controllers. In an embodiment, the one or more managing circuits include an on-chip memory controller for determining row and column address, word line and bit line addresses, memory array enable signals, and data latching signals.

FIG. 1B depicts one embodiment of memory core control circuits 108. As depicted, memory core control circuits 108 include address decoders 120, voltage generators for first control lines 122, voltage generators for second control lines 124 and signal generators for reference signals 126 (described in more detail below). Control lines may include word lines, bit lines, or a combination of word lines and bit lines. First control lines may include first (e.g., selected) word lines and/or first (e.g., selected) bit lines that are used to place memory cells into a first (e.g., selected) state. Second control lines may include second (e.g., unselected) word lines and/or second (e.g., unselected) bit lines that are used to place memory cells into a second (e.g., unselected) state.

Address decoders 120 may generate memory block addresses, as well as row addresses and column addresses for a particular memory block. Voltage generators (or voltage regulators) for first control lines 122 may include one or more voltage generators for generating first (e.g., selected) control line voltages. Voltage generators for second control lines 124 may include one or more voltage generators for generating second (e.g., unselected) control line voltages. Signal generators for reference signals 126 may include one or more voltage and/or current generators for generating reference voltage and/or current signals.

FIGS. 1C-1G depict an embodiment of a memory core organization that includes a memory core having multiple memory bays, and each memory bay having multiple memory blocks. Although a memory core organization is disclosed where memory bays include memory blocks, and memory blocks include a group of memory cells, other organizations or groupings also can be used with the technology described herein.

FIG. 1C depicts an embodiment of memory core 110 of FIG. 1A. As depicted, memory core 110 includes memory bay 130 and memory bay 132. In some embodiments, the number of memory bays per memory core can differ for different implementations. For example, a memory core may include only a single memory bay or multiple memory bays (e.g., 16 or other number of memory bays).

FIG. 1D depicts an embodiment of memory bay 130 in FIG. 1C. As depicted, memory bay 130 includes memory blocks 140-144, read/write circuits 146 and a transfer data latch 148. In some embodiments, the number of memory blocks per memory bay may differ for different implementations. For example, a memory bay may include one or more memory blocks (e.g., 32 or other number of memory blocks per memory bay). Read/write circuits 146 include circuitry for reading and writing memory cells within memory blocks 140-144. In an embodiment, transfer data latch 148 is used for intermediate storage between memory chip controller 104 (FIG. 1A) and memory blocks 140, 142, . . . , 144.

In an embodiment, when host 102 instructs memory chip controller 104 to write data to memory chip 106, memory chip controller 104 writes host data to transfer data latch 148. Read/write circuits 146 then write data from transfer data latch 148 to a specified page in one of memory blocks 140, 142, . . . , 144. In an embodiment, transfer data latch 148 has a size equal to the size of a page. In an embodiment, when host 102 instructs memory chip controller 104 to read data from memory chip 106, read/write circuits 146 read from a specified page into transfer data latch 148, and memory chip controller 104 transfers the read data from transfer data latch 148 to host 102.

As depicted, read/write circuits 146 may be shared across multiple memory blocks within a memory bay. This allows chip area to be reduced because a single group of read/write circuits 146 may be used to support multiple memory blocks. However, in some embodiments, only a single memory block may be electrically coupled to read/write circuits 146 at a particular time to avoid signal conflicts.

In some embodiments, read/write circuits 146 may be used to write one or more pages of data into memory blocks 140-144 (or into a subset of the memory blocks). The memory cells within memory blocks 140-144 may permit direct over-writing of pages (i.e., data representing a page or a portion of a page may be written into memory blocks 140-144 without requiring an erase or reset operation to be performed on the memory cells prior to writing the data).

In one example, memory system 100 of FIG. 1A may receive a write command including a target address and a set of data to be written to the target address. Memory system 100 may perform a read-before-write (RBW) operation to read the data currently stored at the target address and/or to acquire overhead information (e.g., ECC information) before performing a write operation to write the set of data to the target address.

In some cases, read/write circuits 146 may be used to program a particular memory cell to be in one of three or more data/resistance states (i.e., the particular memory cell may include a multi-level memory cell). In one example, read/write circuits 146 may apply a first voltage difference (e.g., 2V) across the particular memory cell to program the particular memory cell into a first state of the three or more data/resistance states or a second voltage difference (e.g., 1V) across the particular memory cell that is less than the first voltage difference to program the particular memory cell into a second state of the three or more data/resistance states.

Applying a smaller voltage difference across the particular memory cell may cause the particular memory cell to be partially programmed or programmed at a slower rate than when applying a larger voltage difference. In another example, read/write circuits 146 may apply a first voltage difference across the particular memory cell for a first time period to program the particular memory cell into a first state of the three or more data/resistance states, and apply the first voltage difference across the particular memory cell for a second time period less than the first time period. One or more program pulses followed by a memory cell verification phase may be used to program the particular memory cell to be in the correct state.

FIG. 1E depicts an embodiment of memory block 140 in FIG. 1D. As depicted, memory block 140 includes a memory array 150, a row decoder 152, and a column decoder 154. Memory array 150 may include a contiguous group of memory cells having contiguous word lines and bit lines. Memory array 150 may include one or more layers of memory cells. Memory array 150 may include a two-dimensional memory array or a three-dimensional memory array.

Row decoder 152 decodes a row address and selects a particular word line in memory array 150 when appropriate (e.g., when reading or writing memory cells in memory array 150). Column decoder 154 decodes a column address and selects one or more bit lines in memory array 150 to be electrically coupled to read/write circuits, such as read/write circuits 146 in FIG. 1D. In one embodiment, the number of word lines is 4K per memory layer, the number of bit lines is 1K per memory layer, and the number of memory layers is four, providing a memory array 150 containing 16M memory cells.

FIG. 1F depicts an embodiment of a memory bay 134. Memory bay 134 is an alternative example implementation for memory bay 130 of FIG. 1D. In some embodiments, row decoders, column decoders, and read/write circuits may be split or shared between memory arrays. As depicted, row decoder 152b is shared between memory arrays 150a and 150b because row decoder 152b controls word lines in both memory arrays 150a and 150b (i.e., the word lines driven by row decoder 152b are shared).

Row decoders 152a and 152b may be split such that even word lines in memory array 150a are driven by row decoder 152a and odd word lines in memory array 150a are driven by row decoder 152b. Row decoders 152c and 152b may be split such that even word lines in memory array 150b are driven by row decoder 152c and odd word lines in memory array 150b are driven by row decoder 152b.

Column decoders 154a and 154b may be split such that even bit lines in memory array 150a are controlled by column decoder 154b and odd bit lines in memory array 150a are driven by column decoder 154a. Column decoders 154c and 154d may be split such that even bit lines in memory array 150b are controlled by column decoder 154d and odd bit lines in memory array 150b are driven by column decoder 154c.

The selected bit lines controlled by column decoder 154a and column decoder 154c may be electrically coupled to read/write circuits 146a. The selected bit lines controlled by column decoder 154b and column decoder 154d may be electrically coupled to read/write circuits 146b. Splitting the read/write circuits into read/write circuits 146a and 146b when the column decoders are split may allow for a more efficient layout of the memory bay.

FIG. 1G depicts an embodiment of memory array 150 of FIG. 1E. Memory array 150 includes an MxN array of memory cells 160. In an embodiment, memory cells 160 in row of memory array 150 are grouped to form a page. For example, a first page P1 includes memory cells 160₁₁, 160₁₂, 160₁₃, . . . , 160_{1N}, a second page P2 includes memory cells 160₂₁, 160₂₂, 160₂₃, . . . , 160_{2N}, and so on. In an embodiment, a page is the smallest unit of writing in memory core 110. In an embodiment, pages P1, P2, P3, . . . , PM of memory array 150 are grouped together to form a block. For example, block B1 includes pages P1, P2, P3, . . . , PM. Block B1 is an example of memory blocks 140, 142, 144 of FIG. 1D. Other arrangements of memory cells, pages and blocks may be used. In an embodiment, memory cells 160 are reversible resistance-switching memory cells. In an embodiment, memory cells 160 are BMC memory cells.

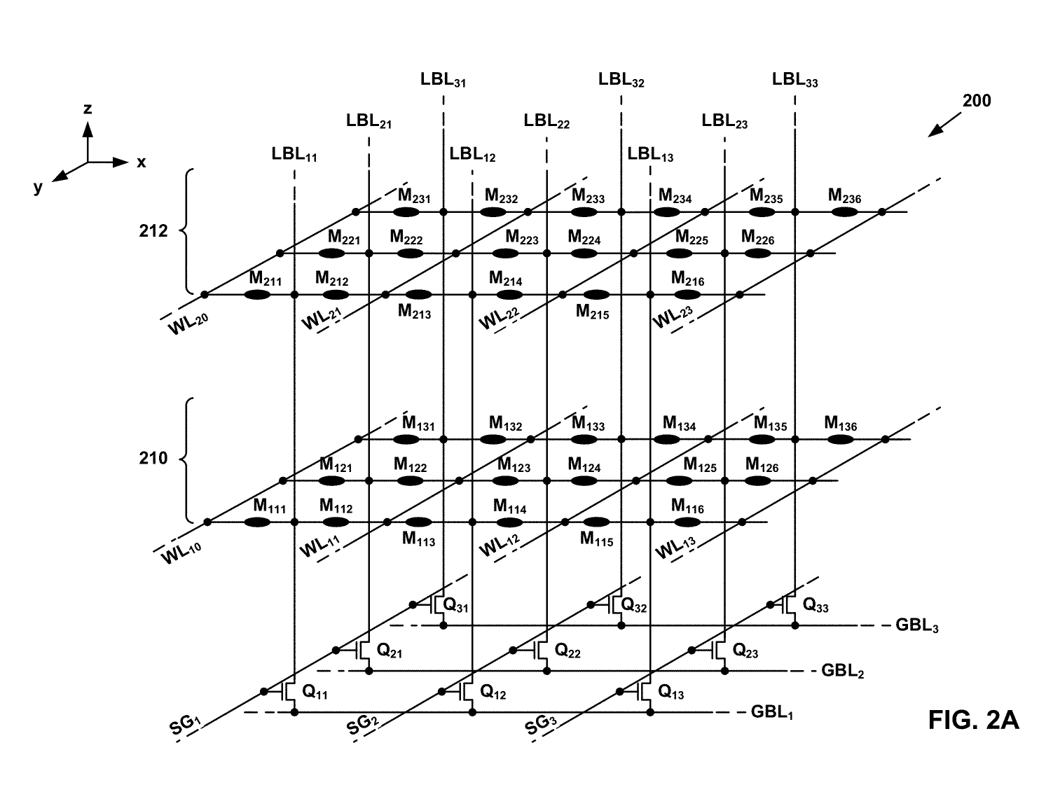

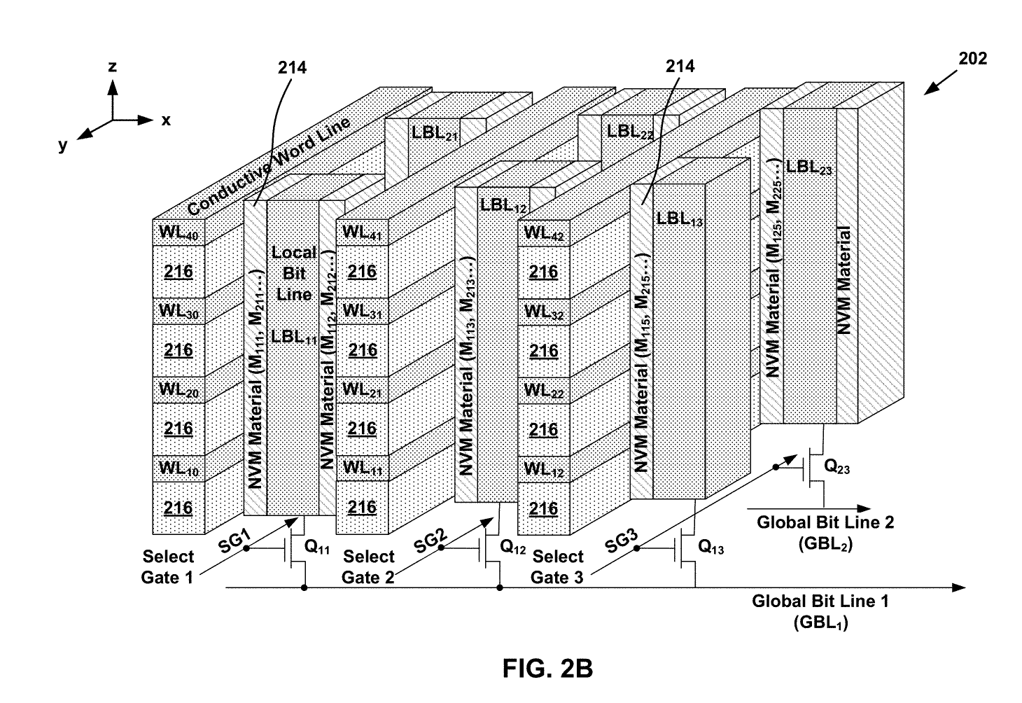

FIG. 2A depicts one embodiment of a portion of a monolithic three-dimensional memory array 200 that includes a first memory level 210, and a second memory level 212 positioned above first memory level 210. Monolithic three-dimensional memory array 200 is one example of an implementation for memory array 150 of FIG. 1E. Local bit lines LBL₁₁-LBL₃₃ are arranged in a first direction (e.g., a vertical or z-direction) and word lines WL₁₀-WL₂₃ are arranged in a second direction (e.g., an x-direction) perpendicular to the first direction. This arrangement of vertical bit lines in a monolithic three-dimensional memory array is one embodiment of a vertical bit line memory array.

As depicted, disposed between the intersection of each local bit line and each word line is a particular memory cell (e.g., memory cell M₁₁₁ is disposed between local bit line LBL₁₁ and word line WL₁₀). The particular memory cell may include a floating gate memory element, a charge trap memory element (e.g., using a silicon nitride material), a reversible resistance-switching memory element, or other similar device. The global bit lines GBL₁-GBL₃ are arranged in a third direction (e.g., a y-direction) that is perpendicular to both the first direction and the second direction.

Each local bit line LBL₁₁-LBL₃₃ has an associated bit line select transistor Q₁₁-Q₃₃, respectively. Bit line select transistors Q₁₁-Q₃₃ may be field effect transistors, such as shown, or may be any other transistors. As depicted, bit line select transistors Q₁₁-Q₃₁ are associated with local bit lines LBL₁₁-LBL₃₁, respectively, and may be used to connect local bit lines LBL₁₁-LBL₃₁ to global bit lines GBL₁-GBL₃, respectively, using row select line SG₁. In particular, each of bit line select transistors Q₁₁-Q₃₁ has a first terminal (e.g., a drain/source terminal) coupled to a corresponding one of local bit lines LBL₁₁-LBL₃₁, respectively, a second terminal (e.g., a source/drain terminal) coupled to a corresponding one of global bit lines GBL₁GBL₃, respectively, and a third terminal (e.g., a gate terminal) coupled to row select line SG₁.

Similarly, bit line select transistors Q₁₂-Q₃₂ are associated with local bit lines LBL₁₂-LBL₃₂, respectively, and may be used to connect local bit lines LBL₁₂-LBL₃₂ to global bit lines GBL₁-GBL₃, respectively, using row select line SG₂. In particular, each of bit line select transistors Q₁₂-Q₃₂ has a first terminal (e.g., a drain/source terminal) coupled to a corresponding one of local bit lines LBL₁₂-LBL₃₂, respectively, a second terminal (e.g., a source/drain terminal) coupled to a corresponding one of global bit lines GBL₁-GBL₃, respectively, and a third terminal (e.g., a gate terminal) coupled to row select line SG₂.

Likewise, bit line select transistors Q₁₃-Q₃₃ are associated with local bit lines LBL₁₃-LBL₃₃, respectively, and may be used to connect local bit lines LBL₁₃-LBL₃₃ to global bit lines GBL₁-GBL₃, respectively, using row select line SG₃. In particular, each of bit line select transistors Q₁₃-Q₃₃ has a first terminal (e.g., a drain/source terminal) coupled to a corresponding one of local bit lines LBL₁₃-LBL₃₃, respectively, a second terminal (e.g., a source/drain terminal) coupled to a corresponding one of global bit lines GBL₁-GBL₃, respectively, and a third terminal (e.g., a gate terminal) coupled to row select line SG₃.

Because a single bit line select transistor is associated with a corresponding local bit line, the voltage of a particular global bit line may be selectively applied to a corresponding local bit line. Therefore, when a first set of local bit lines (e.g., LBL₁₁-LBL₃₁) is biased to global bit lines GBL₁-GBL₃, the other local bit lines (e.g., LBL₁₂-LBL₃₂ and LBL₁₃-LBL₃₃) must either also be driven to the same global bit lines GBL₁-GBL₃ or be floated.

In an embodiment, during a memory operation, all local bit lines within the memory array are first biased to an unselected bit line voltage by connecting each of the global bit lines to one or more local bit lines. After the local bit lines are biased to the unselected bit line voltage, then only a first set of local bit lines LBL₁₁-LBL₃₁ are biased to one or more selected bit line voltages via the global bit lines GBL₁-GBL₃, while the other local bit lines (e.g., LBL₁₂-LBL₃₂ and LBL₁₃-LBL₃₃) are floated. The one or more selected bit line voltages may correspond with, for example, one or more read voltages during a read operation or one or more programming voltages during a programming operation.

In an embodiment, a vertical bit line memory array, such as monolithic three-dimensional memory array 200, includes a greater number of memory cells along the word lines as compared with the number of memory cells along the vertical bit lines (e.g., the number of memory cells along a word line may be more than 10 times the number of memory cells along a bit line). In one example, the number of memory cells along each bit line may be 16 or 32, whereas the number of memory cells along each word line may be 2048 or more than 4096. Other numbers of memory cells along each bit line and along each word line may be used.

In an embodiment of a read operation, the data stored in a selected memory cell (e.g., memory cell M₁₁₁) may be read by biasing the word line connected to the selected memory cell (e.g., selected word line WL₁₀) to a selected word line voltage in read mode (e.g., 0V). The local bit line (e.g., LBL₁₁) coupled to the selected memory cell (M₁₁₁) is biased to a selected bit line voltage in read mode (e.g., 1 V) via the associated bit line select transistor (e.g., Q₁₁) coupled to the selected local bit line (LBL₁₁), and the global bit line (e.g., GBL₁) coupled to the bit line select transistor (Q₁₁). A sense amplifier may then be coupled to the selected local bit line (LBL₁₁) to determine a read current I_{READ} of the selected memory cell (M₁₁₁). The read current I_{READ} is conducted by the bit line select transistor Q₁₁, and may be between about 100 nA and about 500 nA, although other read currents may be used.

In an embodiment of a write operation, data may be written to a selected memory cell (e.g., memory cell M₂₂₁) by biasing the word line connected to the selected memory cell (e.g., WL₂₀) to a selected word line voltage in write mode (e.g., 5V). The local bit line (e.g., LBL₂₁) coupled to the selected memory cell (M₂₂₁) is biased to a selected bit line voltage in write mode (e.g., 0 V) via the associated bit line select transistor (e.g., Q₂₁) coupled to the selected local bit line (LBL₂₁), and the global bit line (e.g., GBL₂) coupled to the bit line select transistor (Q₂₁). During a write operation, a programming current I_{PGRM} is conducted by the associated bit line select transistor Q₂₁, and may be between about 3 uA and about 6 uA, although other programming currents may be used.

During the write operation described above, the word line (e.g., WL₂₀) connected to the selected memory cell (M₂₂₁) may be referred to as a “selected word line,” and the local bit line (e.g., LBL₂₁) coupled to the selected memory cell (M₂₂₁) may be referred to as the “selected local bit line.” All other word lines coupled to unselected memory cells may be referred to as “unselected word lines,” and all other local bit lines coupled to unselected memory cells may be referred to as “unselected local bit lines.” For example, if memory cell M₂₂₁ is the only selected memory cell in monolithic three-dimensional memory array 200, word lines WL₁₀-WL₁₃ and WL₂₁-WL₂₃ are unselected word lines, and local bit lines LBL₁₁, LBL₃₁, LBL₁₂-LBL₃₂, and LBL₁₃-LBL₃₃ are unselected local bit lines.

FIG. 2B depicts an embodiment of a portion of a monolithic three-dimensional memory array 202 that includes vertical strips of a non-volatile memory material. The portion of monolithic three-dimensional memory array 202 depicted in FIG. 2B may include an implementation for a portion of the monolithic three-dimensional memory array 200 depicted in FIG. 2A.

Monolithic three-dimensional memory array 202 includes word lines WL₁₀, WL₁₁, WL₁₂, . . . , WL₄₂ that are formed in a first direction (e.g., an x-direction), vertical bit lines LBL₁₁, LBL₁₂, LBL₁₃, . . . , LBL₂₃ that are formed in a second direction perpendicular to the first direction (e.g., a z-direction), and non-volatile memory material 214 formed in the second direction (e.g., the z-direction). A spacer 216 made of a dielectric material (e.g., silicon dioxide, silicon nitride, or other dielectric material) is disposed between adjacent word lines WL₁₀, WL₁₁, WL₁₂, . . . , WL₄₂.

Each non-volatile memory material 214 may include, for example, an oxide material, a reversible resistance-switching memory material (e.g., one or more metal oxide layers such as nickel oxide, hafnium oxide, or other similar metal oxide materials, a phase change material, a barrier modulated switching structure or other similar reversible resistance-switching memory material), a ferroelectric material, or other non-volatile memory material.

Each non-volatile memory material 214 may include a single material layer or multiple material layers. In an embodiment, each non-volatile memory material 214 includes a barrier modulated switching structure. Example barrier modulated switching structures include a semiconductor material layer (e.g., an amorphous silicon layer) adjacent a conductive oxide material layer (e.g., a titanium oxide layer). Other example barrier modulated switching structures include a thin (e.g., less than about 2 nm) barrier oxide material (e.g., an aluminum oxide layer) disposed between a semiconductor material layer (e.g., an amorphous silicon layer) and a conductive oxide material layer (e.g., a titanium oxide layer). Still other example barrier modulated switching structures include a barrier oxide material (e.g., an aluminum oxide layer) disposed adjacent a conductive oxide material layer (e.g., a titanium oxide layer), with no semiconductor material layer (e.g., amorphous silicon) in the barrier modulated switching structure. Such multi-layer embodiments may be used to form BMC memory elements.

In an embodiment, each non-volatile memory material 214 may include a single continuous layer of material that may be used by a plurality of memory cells or devices. In an embodiment, each memory cell includes a portion of non-volatile memory material 214 disposed between a first conductor (e.g., a word line) and a second conductor (e.g., a bit line).

In an embodiment, portions of the non-volatile memory material 214 may include a part of a first memory cell associated with the cross section between WL₁₂ and LBL₁₃ and a part of a second memory cell associated with the cross section between WL₂₂ and LBL₁₃. In some cases, a vertical bit line, such as LBL₁₃, may include a vertical structure (e.g., a rectangular prism, a cylinder, or a pillar) and the non-volatile material may completely or partially surround the vertical structure (e.g., a conformal layer of phase change material surrounding the sides of the vertical structure).

As depicted, each of the vertical bit lines LBL₁₁, LBL₁₂, LBL₁₃, . . . , LBL₂₃ may be connected to one of a set of global bit lines via an associated vertically-oriented bit line select transistor (e.g., Q₁₁, Q₁₂, Q₁₃, Q₂₃). Each vertically-oriented bit line select transistor may include a MOS device (e.g., an NMOS device) or a vertical thin-film transistor (TFT).

In an embodiment, each vertically-oriented bit line select transistor is a vertically-oriented pillar-shaped TFT coupled between an associated local bit line pillar and a global bit line. In an embodiment, the vertically-oriented bit line select transistors are formed in a pillar select layer formed above a CMOS substrate, and a memory layer that includes multiple layers of word lines and memory elements is formed above the pillar select layer.

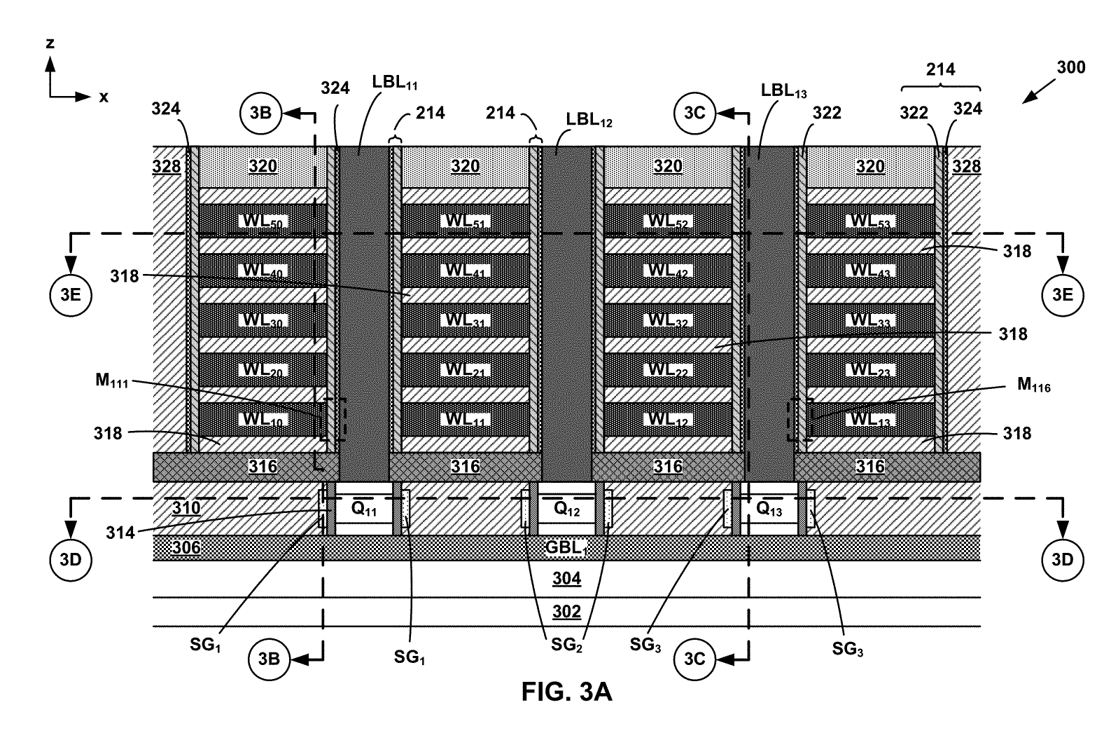

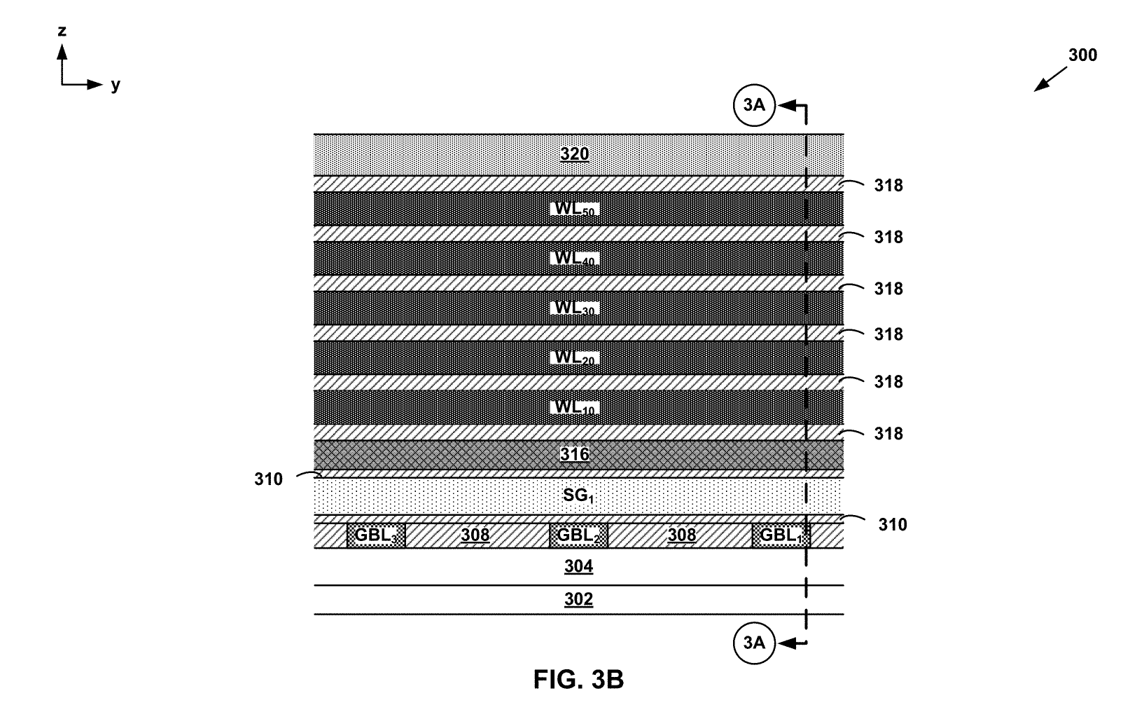

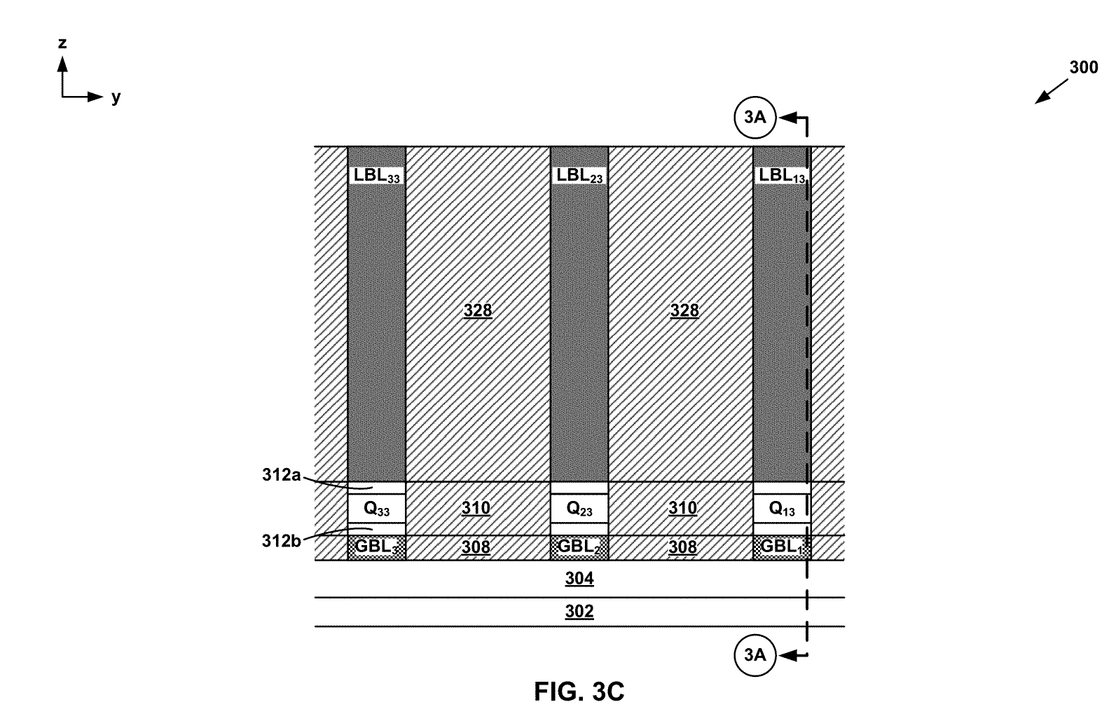

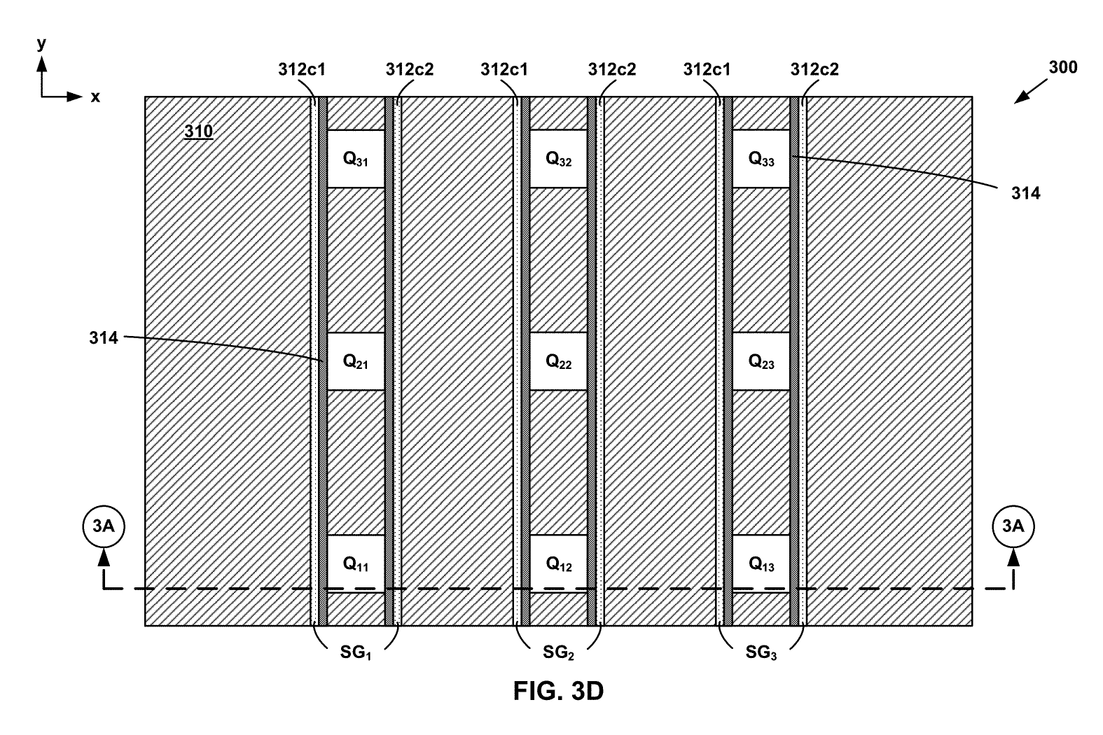

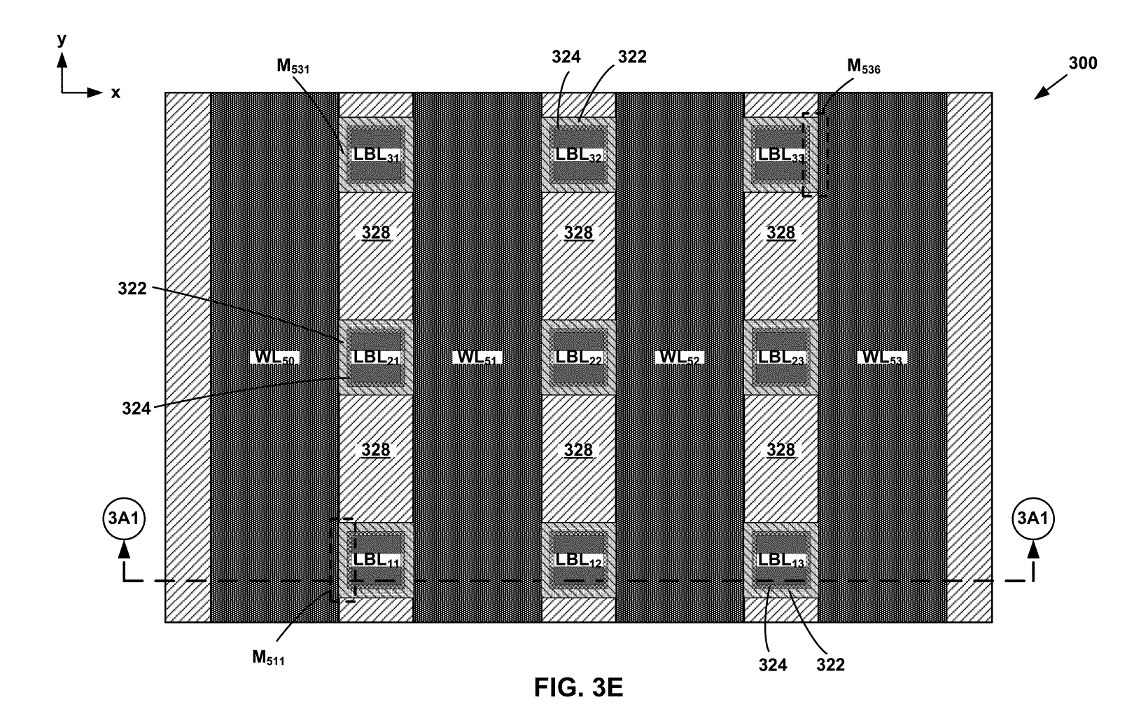

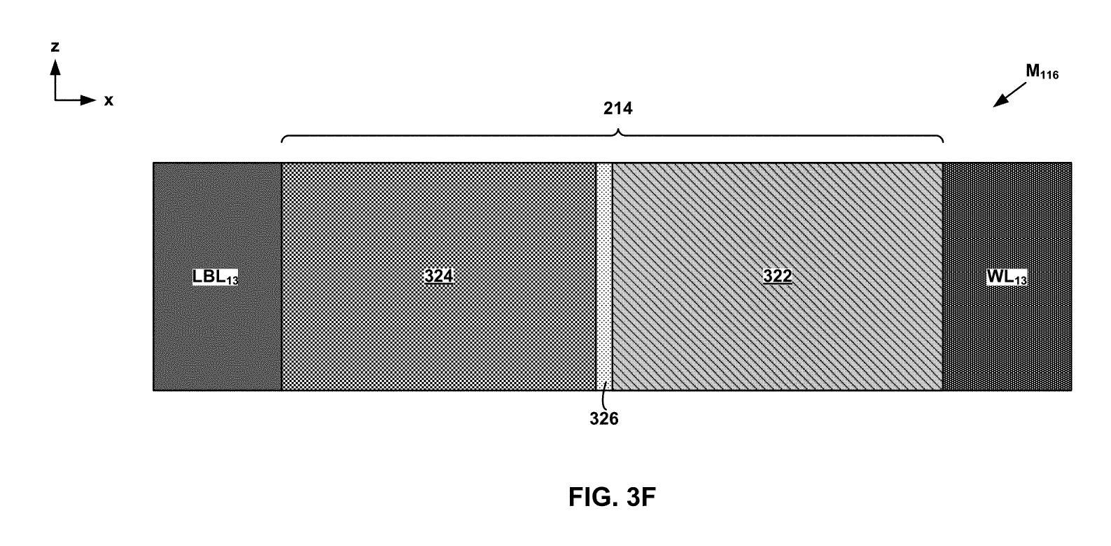

FIGS. 3A-3F depict various views of an embodiment of a portion of a monolithic three-dimensional memory array 300 that includes vertical strips of a non-volatile memory material. The physical structure depicted in FIGS. 3A-3F may include one implementation for a portion of the monolithic three-dimensional memory array depicted in FIG. 2B.

Monolithic three-dimensional memory array 300 includes vertical bit lines LBL₁₁-LBL₃₃ arranged in a first direction (e.g., a z-direction), word lines WL₁₀, WL₁₁, . . . , WL₅₃ arranged in a second direction (e.g., an x-direction) perpendicular to the first direction, and row select lines SG₁, SG₂, SG₃ arranged in the second direction, and global bit lines GBL₁, GBL₂, GBL₃ arranged in a third direction (e.g., a y-direction) perpendicular to the first and second directions.

Vertical bit lines LBL₁₁-LBL₃₃ are disposed above global bit lines GBL₁, GBL₂, GBL₃, which each have a long axis in the second (e.g., x-direction). Person of ordinary skill in the art will understand that monolithic three-dimensional memory arrays, such as monolithic three-dimensional memory array 300 may include more or fewer than twenty word lines, three row select lines, three global bit lines, and nine vertical bit lines.

In an embodiment, global bit lines GBL₁, GBL₂, GBL₃ are disposed above a substrate 302, such as a silicon, germanium, silicon-germanium, undoped, doped, bulk, silicon-on-insulator (“SOI”) or other substrate with or without additional circuitry. In an embodiment, an isolation layer 304, such as a layer of silicon dioxide, silicon nitride, silicon oxynitride or any other suitable insulating layer, is formed above substrate 302.

In an embodiment, a first dielectric material layer 308 (e.g., silicon dioxide) and a second dielectric material layer 310 (e.g., silicon dioxide) are formed above isolation layer 304. Global bit lines GBL₁, GBL₂, GBL₃ include a conductive material layer 306 (e.g., tungsten) and are disposed above isolation layer 304 and are separated from one another by first dielectric material layer 308.

Vertically-oriented bit line select transistors Q₁₁-Q₃₃ are disposed above global bit lines GBL₁, GBL₂, GBL₃ and are separated from one another by second dielectric material layer 310. Vertically-oriented bit line select transistors Q₁₁-Q₁₃ are disposed above and electrically coupled to global bit line GBL₁, vertically-oriented bit line select transistors Q₂₁-Q₂₃ are disposed above and electrically coupled to global bit line GBL₂, and vertically-oriented bit line select transistors Q₃₁-Q₃₃ are disposed above and electrically coupled to global bit line GBL₃.

Vertically-oriented bit line select transistors Q₁₁-Q₃₃ may be field effect transistors, although other transistors types may be used. In an embodiment, each of vertically-oriented bit line select transistors Q₃₁-Q₃₃ has a height between about 150 nm and about 500 nm. Other height values may be used.

Each of vertically-oriented bit line select transistors Q₁₁-Q₃₃ has a first terminal 312a (e.g., a drain/source terminal), a second terminal 312b (e.g., a source/drain terminal), a first control terminal 312c1 (e.g., a first gate terminal) and a second control terminal 312c2 (e.g., a second gate terminal). First gate terminal 312c1 and second gate terminal 312c2 may be disposed on opposite sides of the vertically-oriented bit line select transistor. A gate dielectric material 314 (e.g., SiO₂) is disposed between first gate terminal 312c1 and first terminal 312a and second terminal 312b, and also is disposed between second gate terminal 312c2 and first terminal 312a and second terminal 312b.

First gate terminal 312c1 may be used to selectively induce a first electrically conductive channel between first terminal 312a and second terminal 312b of the transistor, and second gate terminal 312c2 may be used to selectively induce a second electrically conductive channel between first terminal 312a and second terminal 312b of the transistor. In an embodiment, first gate terminal 312c1 and second gate terminal 312c2 are coupled together to form a single control terminal 312c that may be used to collectively turn ON and OFF the vertically-oriented bit line select transistor.

Row select lines SG₁, SG₂, SG₃ are disposed above global bit lines GBL₁, GBL₂ and GBL₃, and form gate terminals 312c of vertically-oriented bit line select transistors Q₁₁-Q₃₃. In particular, row select line SG₁ forms the gate terminals of vertically-oriented bit line select transistors Q₁₁, Q₂₁ and Q₃₁, row select line SG₂ forms the gate terminals of vertically-oriented bit line select transistors Q₁₂, Q₂₂ and Q32, and row select line SG₃ forms the gate terminals of vertically-oriented bit line select transistors Q₁₃, Q₂₃ and Q₃₃.

A first etch stop layer 316 (e.g., aluminum oxide) is disposed above second dielectric material layer 310. A stack of word lines WL₁₀, WL₁₁, . . . , WL₅₃ is disposed above first etch stop layer 316, with a third dielectric material layer 318 (e.g., silicon dioxide) separating adjacent word lines. A second etch stop layer 320 (e.g., polysilicon) may be formed above the stack of word lines WL₁₀, WL₁₁, . . . , WL₅₃. Each of word lines WL₁₀, WL₁₁, . . . , WL₅₃ includes a conductive material layer (e.g., titanium nitride, tungsten, tantalum nitride or other similar electrically conductive material, or combination thereof).

In an embodiment, non-volatile memory material 214 is disposed adjacent word lines WL₁₀, WL₁₁, . . . , WL₅₃. Non-volatile memory material 214 may include, for example, an oxide layer, a reversible resistance-switching material (e.g., one or more metal oxide layers such as nickel oxide, hafnium oxide, or other similar metal oxide materials, a phase change material, a barrier modulated switching structure or other similar reversible resistance-switching memory material), a ferroelectric material, or other non-volatile memory material.

Non-volatile memory material 214 may include a single continuous layer of material that may be used by a plurality of memory cells or devices. For simplicity, non-volatile memory material 214 also will be referred to in the remaining discussion as reversible resistance-switching memory material 214.

Reversible resistance-switching memory material 214 may include a single material layer or multiple material layers. In an embodiment, reversible resistance-switching memory material 214 includes a barrier modulated switching structure. In some embodiments, barrier modulated switching structures include a semiconductor material layer (e.g., amorphous silicon) and a conductive oxide material layer (e.g., titanium oxide). In some embodiments, barrier modulated switching structures include a thin (e.g., less than about 2 nm) barrier oxide material disposed between a semiconductor material layer and a conductive oxide material layer.

In an embodiment, reversible resistance-switching memory material 214 includes a barrier modulated switching structure that includes a semiconductor material layer 322 and a conductive oxide material layer 324. In an embodiment, semiconductor material layers 322 are disposed adjacent word lines WL₁₀, WL₁₁, . . . , WL₅₃, and conductive oxide material layers 324 are disposed adjacent vertical bit line LBL₁₁-LBL₃₃. In an embodiment, an adhesion material layer (not shown) may be disposed between semiconductor material layers 322 and adjacent word lines WL₁₀, WL₁₁, . . . , WL₅₃.

In embodiments, semiconductor material layer 322 has a thickness between about 3 nm and about 15 nm, and includes one or more of carbon, germanium, silicon, tantalum nitride, tantalum silicon nitride, or other similar semiconductor material. In embodiments, conductive oxide material layer 324 has a thickness between about 5 nm and about 25 nm, and includes one or more of aluminum-doped zinc oxide, aluminum-doped zirconium oxide, cerium oxide, indium tin oxide, niobium-doped strontium titanate, praseodymium calcium manganese oxide, titanium oxide, tungsten oxide, zinc oxide, or other similar conductive oxide material. Other semiconductor materials, conductive oxide materials, and thicknesses may be used.

In embodiments, each of semiconductor material layer 322, and conductive oxide material layer 324 may be amorphous, polycrystalline, nano-crystalline, or single crytalline, and each may be formed by chemical vapor deposition (CVD), physical vapor deposition (PVD), atomic layer deposition (ALD), atomic layer deposition nanolaminates, or other method.

Vertical bit lines LBL₁₁-LBL₃₃ are disposed adjacent reversible resistance-switching memory material 214, and are formed of a conductive material (e.g., titanium nitride). Vertical bit lines LBL₁₁-LBL₃₃ are separated from one another by a fourth dielectric material layer 328 (e.g., silicon dioxide). In some embodiments, each of vertical bit lines LBL₁₁-LBL₃₃ includes a vertical structure (e.g., a rectangular prism, a cylinder, or a pillar), and the vertical strip of reversible resistance-switching memory material 214 may completely or partially surround the vertical structure (e.g., a conformal layer of reversible resistance-switching material surrounding the sides of the vertical structure).

A memory cell is disposed between the intersection of each vertical bit line and each word line. In an embodiment, each memory cell includes a portion of reversible resistance-switching memory material 214 disposed between a first conductor (e.g., one of word lines WL₁₀, WL₁₁, . . . , WL₅₃) and a second conductor (e.g., one of bit lines LBL₁₁-LBL₃₃).

For example, a memory cell M₁₁₁ is disposed between vertical bit line LBL₁₁ and word line WL₁₀, a memory cell M₁₁₆ is disposed between vertical bit line LBL₁₃ and word line WL₁₃, a memory cell M₅₁₁ is disposed between vertical bit line LBL₁₁ and word line WL₅₀, a memory cell M₅₃₆ is disposed between vertical bit line LBL₃₃ and word line WL₅₀, and so on. In an embodiment, monolithic three-dimensional memory array 300 includes ninety memory cells M₁₁₁, M₁₁₂, . . . , M₅₃₆. Persons of ordinary skill in the art will understand that monolithic three-dimensional memory arrays may include more or fewer than ninety memory cells.

In an embodiment, portions of the reversible resistance-switching memory material 214 may include a part of memory cell M₁₁₁ associated with the cross section between word line WL₁₀ and LBL₁₁, and a part of memory cell M₂₁₁ associated with the cross section between word line WL₂₀ and LBL₁₁, and so on.

Each of memory cells M₁₁₁, M₁₁₂, . . . , M₅₃₆ may include a floating gate device, a charge trap device (e.g., using a silicon nitride material), a resistive change memory device, or other type of memory device. In an embodiment, each of memory cells M₁₁₁, M₁₁₂, . . . , M₅₃₆ is a BMC memory cell that includes a barrier modulated switching structure. FIG. 3F depicts an embodiment of a BMC memory cell M₁₁₆ that includes a reversible resistance-switching memory material 214 disposed between a first conductor (word line WL₁₃) and a second conductor (local bit line LBL₁₃).

In an embodiment, each reversible resistance-switching memory material 214 is a barrier modulated switching structure that includes a reactive layer 326 between semiconductor material layer 322 and conductive oxide material layer 324. In embodiments, reactive layer 326 may have a thickness between about 1 nm and about 10 nm, and forms as a result of semiconductor material layer 322 reacting with oxygen from conductive oxide material layer 324.

For example, if semiconductor material layer 322 includes amorphous silicon, and conductive oxide material layer 324 includes yttria-stabilized zirconia, reactive layer 326 includes silicon dioxide (a reaction of amorphous silicon from semiconductor material layer 322 with oxygen from the yttria-stabilized zirconia conductive oxide material layer 324). Other similar reactive layers 326 may be formed from a reaction of semiconductor material layer 322 with oxygen in conductive oxide material layer 324. In other embodiments, reactive layer 326 may be a deposited material layer.

Vertically-oriented bit line select transistors Q₁₁-Q₃₃ may be used to select a corresponding one of vertical bit lines LBL₁₁-LBL₃₃. Vertically-oriented bit line select transistors Q₁₁-Q₃₃ may be field effect transistors, although other transistors types may be used.

Thus, the first gate terminal and the second gate terminal of each of vertically-oriented bit line select transistors Q₁₁-Q₃₃ may be used to turn ON and OFF vertically-oriented bit line select transistors Q₁₁-Q₃. Without wanting to be bound by any particular theory, for each of vertically-oriented bit line select transistors Q₁₁-Q₃₃, it is believed that the current drive capability of the transistor may be increased by using both the first gate terminal and the second gate terminal to turn ON the transistor. For simplicity, the first and second gate terminal of each of select transistors Q₁₁-Q₃₃ will be referred to as a single gate terminal.

Vertically-oriented bit line select transistors Q₁₁, Q₁₂, Q₁₃ are used to selectively connect/disconnect vertical bit lines LBL₁₁, LBL₁₂, and LBL₁₃ to/from global bit line GBL₁ using row select lines SG₁, SG₂, SG₃, respectively. In particular, each of vertically-oriented bit line select transistors Q₁₁, Q₁₂, Q₁₃ has a first terminal (e.g., a drain./source terminal) coupled to a corresponding one of vertical bit lines LBL₁₁, LBL₁₂, and LBL₁₃, respectively, a second terminal (e.g., a source/drain terminal) coupled to global bit line GBL₁, and a control terminal (e.g., a gate terminal) coupled to row select line SG₁, SG₂, SG₃, respectively.

Row select lines SG₁, SG₂, SG₃ are used to turn ON/OFF vertically-oriented bit line select transistors Q₁₁, Q₁₂, Q₁₃, respectively, to connect/disconnect vertical bit lines LBL₁₁, LBL₁₂, and LBL₁₃, respectively, to/from global bit line GBL₁.

Likewise, vertically-oriented bit line select transistors Q₁₁, Q₂₁, . . . , Q₃₃ are used to selectively connect/disconnect vertical bit lines LBL₁₁, LBL₂₁, and LBL₃₁, respectively, to global bit lines GBL₁, GBL₂, GBL₃, respectively, using row select line SG₁. In particular, each of vertically-oriented bit line select transistors Q₁₁, Q₂₁, Q₃₁ has a first terminal (e.g., a drain./source terminal) coupled to a corresponding one of vertical bit lines LBL₁₁, LBL₂₁, and LBL₃₁, respectively, a second terminal (e.g., a source/drain terminal) coupled to a corresponding one of global bit lines GBL₁, GBL₂, GBL₃, respectively, and a control terminal (e.g., a gate terminal) coupled to row select line SG₁. Row select line SG₁ is used to turn ON/OFF vertically-oriented bit line select transistors Q₁₁, Q₂₁, Q₃₁ to connect/disconnect vertical bit lines LBL₁₁, LBL₂₁, and LBL₃₁, respectively, to/from global bit lines GBL₁, GBL₂, GBL₃, respectively.

Similarly, vertically-oriented bit line select transistors Q₁₃, Q₂₃, Q₃₃ are used to selectively connect/disconnect vertical bit lines LBL₁₃, LBL₂₃, and LBL₃₃, respectivelyto/from global bit lines GBL₁, GBL₂, GBL₃, respectively, using row select line SG₃. In particular, each of vertically-oriented bit line select transistors Q₁₃, Q₂₃, Q₃₃ has a first terminal (e.g., a drain./source terminal) coupled to a corresponding one of vertical bit lines LBL₁₃, LBL₂₃, and LBL₃₃, respectively, a second terminal (e.g., a source/drain terminal) coupled to a corresponding one of global bit lines GBL₁, GBL₂, GBL₃, respectively, and a control terminal (e.g., a gate terminal) coupled to row select line SG₃. Row select line SG₃ is used to turn ON/OFF vertically-oriented bit line select transistors Q₁₃, Q₂₃, Q₃₃ to connect/disconnect vertical bit lines LBL₁₃, LBL₂₃, and LBL₃₃, respectively, to/from global bit lines GBL₁, GBL₂, GBL₃, respectively.

As described above, in an embodiment, each of memory cells M₁₁₁, M₁₁₂, . . . , M₅₃₆ is a BMC memory cell that includes a barrier modulated switching structure, and FIG. 3F depicts an embodiment of one such BMC memory cell M₁₁₆ that includes a reversible resistance-switching memory material 214 disposed between a first conductor (e.g., word line WL₁₃) and a second conductor (e.g., local bit line LBL₁₃). In an embodiment, reversible resistance-switching memory material 214 includes a reactive layer 326 between semiconductor material layer 322 and conductive oxide material layer 324.

Without wanting to be bound by any particular theory, it is believed that the resistance-switching effect in BMC memory cells predominantly occurs as a result of creation and movement of oxygen vacancies between different material layers in the BMC memory cells, which causes the BMC memory cell to reversibly switch between two or more resistance states (e.g., a low resistance “SET” state and a high resistance “RESET” state). For example, referring to BMC memory cell M₁₁₆ of FIG. 3F, it is believed that the resistance-switching effect predominantly occurs as a result of creation and movement of oxygen vacancies between conductive oxide material layer 324 and reactive layer 326.

Such resistance-switching occurs by virtue of applying voltage pulses of the appropriate polarity between the first conductor (e.g., word line WL₁₃) and the second conductor (e.g., local bit line LBL₁₃) of the BMC memory cell. As used herein, such a resistance-switching mechanism is referred to as a “bulk switching” mode of operation. BMC memory cells may be reversibly switched between resistance states for numerous program and erase (P/E) cycles.

However, without wanting to be bound by any particular theory, it is believed that after some number of P/E cycles, the resistance-switching mechanism of BMC memory cells no longer predominantly occurs as a result of bulk switching, but instead begins to occur as a result of creation and destruction of conductive filaments between the first conductor (e.g., word line WL₁₃ in FIG. 3F) and the second conductor (e.g., local bit line LBL₁₃ in FIG. 3F) of the memory cell. As used herein, such a resistance-switching mechanism is referred to as a “filamentary switching” mode of operation.

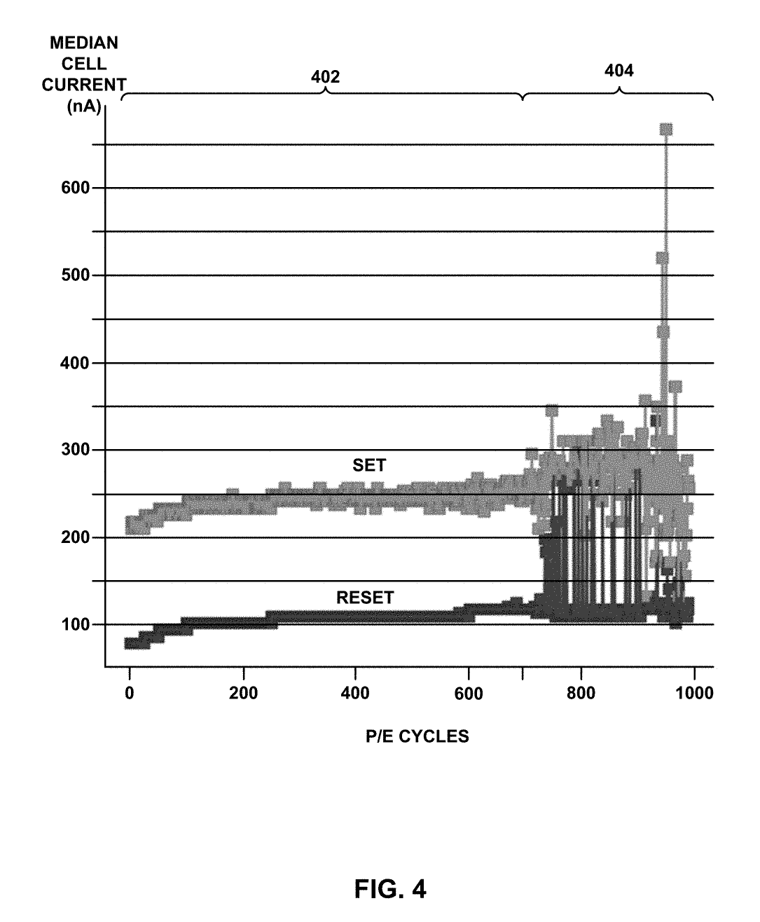

FIG. 4 illustrates example electrical characteristics (median cell current versus P/E cycle) of a population of BMC memory cells. The diagram illustrates a first region of operation 402 from 0 to about 700 P/E cycles, and a second region of operation 404 of greater that about 700 P/E cycles. In first region of operation 402 the cell currents in SET and RESET states are tightly distributed over relatively narrow ranges of current. Without wanting to be bound by any particular theory, it is believed that in first region of operation 402, the BMC memory cells predominantly exhibit bulk switching behavior. In second region of operation 404 the variation in cell current substantially increases. Without wanting to be bound by any particular theory, it is believed that in second region of operation 404, the BMC memory cells exhibit predominantly filamentary switching behavior.

In an embodiment, first region of operation 402 (bulk switching) is more desirable than second region of operation 404 (filamentary switching). In particular, on a P/E cycle-by-cycle basis, it is believed that BMC memory cell current is more predictable and repeatable, and the memory cell switching behavior is more deterministic in first region of operation 402 than second region of operation 404.

In an embodiment, BMC memory cells are operated in first region of operation 402, but are deemed to be “bad” memory cells and are “retired” from further use for host data storage at a point before the cells begins operating in second region of operation 404. In an embodiment, retired BMC memory cells are deemed to be at an end-of-life (EOL), and are no longer used for host data storage.

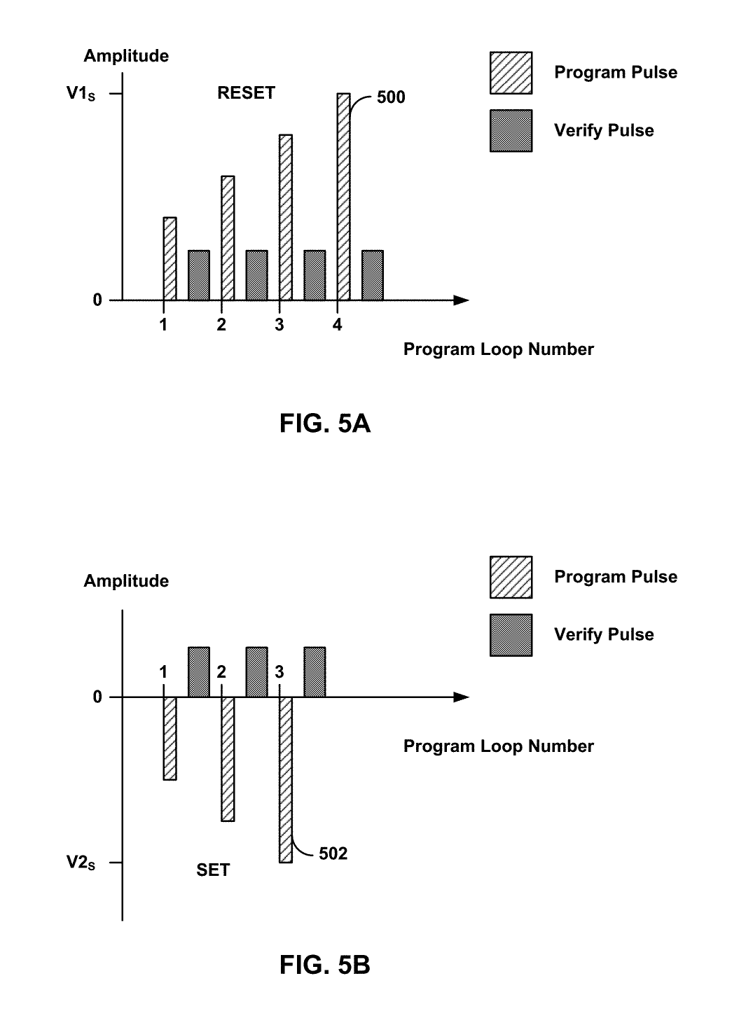

FIGS. 5A-5B illustrate example waveforms for programming memory cells, such as memory cells M₁₁₁, M₁₁₂, . . . , M₅₃₆ of FIGS. 3A-3F, using an incremental step pulse programming (ISPP) method. The horizontal axis depicts a program loop number and the vertical axis depicts pulse amplitude (e.g., a word line voltage).

In an embodiment, a programming operation for a memory cell involves applying a pulse train to a selected word line coupled to the memory cell, where the pulse train includes one or more program loops. Each program loop includes a program pulse having a programming voltage, and a verify pulse having a verify voltage.

In each successive program loop, the programming voltage magnitude increases. Verify operations are performed to determine if the memory cell being programmed has reached a desired programming state (e.g., RESET or SET) and has completed programming. If programming has not completed (e.g., the memory cell verify current is not within a desired range), a next successive program loop is used with the next incremental programming voltage. When programming has completed for a memory cell (e.g., the memory cell verify current is within a desired range), the memory cell is locked out from further programming.

The programming voltage used in the last ISPP program loop before memory cell lockout is referred to herein as the “successful voltage.” In other words, the “successful voltage” is the voltage of the applied ISPP program pulse that successfully programs the memory cell to the desired programming state (e.g., SET or RESET).

FIG. 5A depicts an example ISPP pulse train for programming a memory cell to a first state (e.g., RESET), which in this embodiment uses positive amplitude program pulses, and FIG. 5B depicts an example ISPP pulse train for programming the memory cell to a second state (e.g., SET), which in this embodiment uses negative amplitude program pulses. In this embodiment, each program loop includes verify pulses that have positive amplitudes for all programming operations. In other embodiments, negative amplitude program pulses may be used to program a memory cell to a first state (e.g., RESET), and positive amplitude program pulses may be used to program a memory cell to a second state (e.g., SET).

In FIG. 5A, an ISPP pulse train that includes four program loops programs the memory cell to the first state (e.g., RESET), with program pulse 500 being the ISPP program pulse that successfully programs the memory cell to the first state. Accordingly, the first state successful voltage is V1_{S}, the voltage of program pulse 500. Persons of ordinary skill in the art will understand that more or fewer than four program loops may be used to program a memory cell to a first state (e.g., RESET).

In FIG. 5B, an ISPP pulse train that includes three program loops programs the memory cell to the second state (e.g., SET), with program pulse 502 being the ISPP program pulse that successfully programs the memory cell to the second state. Accordingly, the second state successful voltage is V2_{S}, the voltage of program pulse 502. Persons of ordinary skill in the art will understand that more or fewer than three program loops may be used to program a memory cell to a second state (e.g., SET).

Referring again to FIG. 4, for BMC memory cells operating in first region of operation 402 (bulk switching), programming is highly deterministic. In particular, if a first programming voltage V1 is applied to a BMC memory cell, the data state of the BMC memory cell will be (to a high degree of predictability) a first data state S1, if a second programming voltage V2 is applied to the BMC memory cell, the data state of the BMC memory cell will be (to a high degree of predictability) a second data state S2, if a third programming voltage V3 is applied to the BMC memory cell, the data state of the BMC memory cell will be (to a high degree of predictability) a third data state S3, and so on.

Likewise, referring to FIGS. 5A and 5B, after a first state successful voltage V1_{S} (e.g., for RESET programming) and a second state successful voltage V2_{S} (e.g., for RESET programming) have been determined for a BMC memory cell, the BMC memory cell can thereafter be repeatedly programmed to the first state and the second state by repeatedly applying the first state successful voltage V1_{S} and the second state successful voltage V2_{S}, respectively, to the BMC memory cell.

In other words, rather than requiring four program loops for first state programming and three program loops for second state programming, a single program loop using first state successful voltage V1_{S} can be used to program the BMC memory cell to the first state, and a single program loop using second state successful voltage V2_{S} can be used to program the BMC memory cell to the second state.

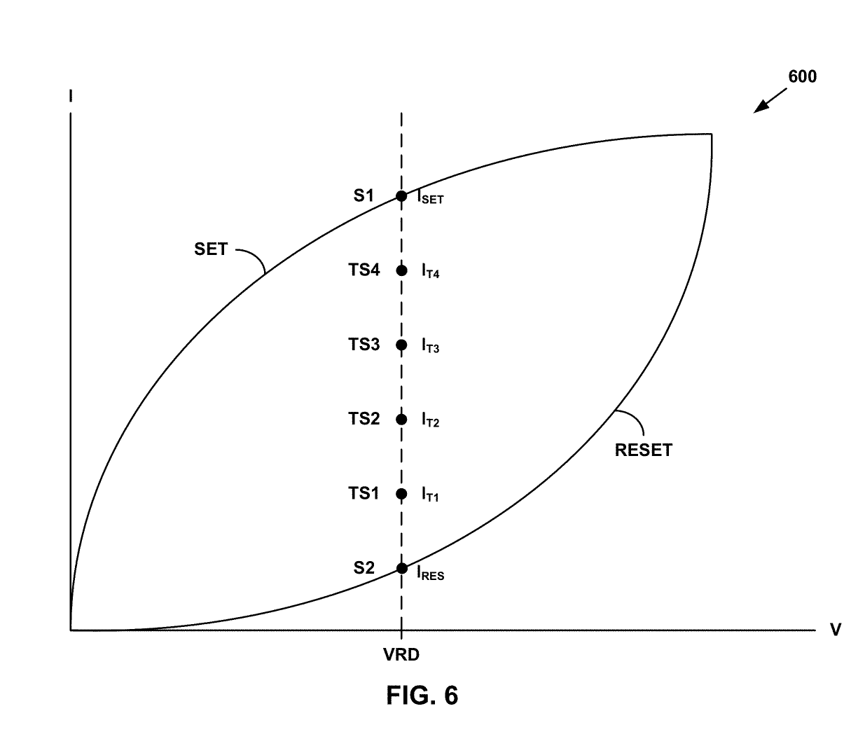

FIG. 6 is a diagram of example current-versus-voltage characteristics 600 of BMC memory cells, such as memory cells M₁₁₁, M₁₁₂, . . . , M₅₃₆ of FIGS. 3A-3F. In an embodiment, the upper solid curve depicts characteristics for a programming state S1, and the lower solid curve depicts characteristics for a programming state S2. At a read voltage VRD, BMC memory cells programmed to programming state S1 have a first read current I_{SET}, and BMC memory cells programmed to programming state S2 have a second read current I_{RST}.

In embodiments, the difference between first read current I_{SET} and second read current I_{RST} (sometimes referred to as the programming window) may be between about 100 μA and about 100 nA, although larger or smaller current differences may be used. If the programming windows is sufficiently large, BMC memory cells may be programmed to more than two states S1 and S2. Indeed, BMC memory cells may be programmed to one or more programming states between programming state S1 and programming state S2.

In the embodiment of FIG. 6, BMC memory cells may be programmed to any of first target programming state TS1, second target programming state TS2, third target programming state TS3 and fourth target programming state TS4 between programming state S1 and programming state S2. At read voltage VRD, BMC memory cells programmed to first target programming state TS1, second target programming state TS2, third target programming state TS3, and fourth target programming state TS4 have a first target read current I_{T1}, a second target read current I_{T2}, a third target read current I_{T3}, and a fourth target read current I_{T4}, respectively. More or fewer than four target programming states may be used.

In an embodiment, a BMC memory cell is programmed to a first programming state, and is then programmed from the first programming state to one of the target programming states. In an embodiment, the first programming state (e.g., S1) has a first read current (e.g., I_{SET}) greater than the target read currents (e.g., _{T1}, I_{T2}, I_{T3}, and I_{T4}) of each of the target programming states (e.g., TS1, TS2, TS3 and TS4, respectively). In another embodiment, the first programming state (e.g., S2) has a first read current (e.g., I_{RST}) less than the target read currents (e.g., I_{T1}, I_{T2}, I_{T3}, and I_{T4}) of each of the target programming states (e.g., TS1, TS2, TS3 and TS4, respectively).

In an embodiment, one or more programming pulses having a first polarity are applied to the BMC memory cell to program the memory cell to the first programming state, and then one or more programming pulses having a second polarity opposite the first polarity are applied to the BMC memory cell to program the memory cell from the first programming state to one of the target programming states.

For example, one or more SET programming pulses having a negative polarity are applied to the BMC memory cell to program the memory cell to a first programming state S1, and then one or more RESET programming pulses having a positive polarity are applied to the BMC memory cell to program the memory cell from first programming state S1 to one of target programming states TS1, TS2, TS3 and TS4.

In another example, one or more RESET programming pulses having a positive polarity are applied to the BMC memory cell to program the memory cell to a first programming state S2, and then one or more SET programming pulses having a negative polarity are applied to the BMC memory cell to program the memory cell from first programming state S2 to one of target programming states TS1, TS2, TS3 and TS4.

As described above, and as depicted in FIG. 6, BMC memory cells may be programmed to any of four target programming states TS1, TS2, TS3 and TS4 either from programming state S1 or programming state S2. For example, to program a BMC memory cell to the second target programming state TS2, one or more negative amplitude SET pulses may be used to program the BMC memory cell to a first programming state S1, and then one or more positive amplitude RESET pulses may be used to program the BMC memory cell from first programming state S1 to the second target programming state TS2.

Alternatively, one or more positive amplitude RESET pulses may be used to program the BMC memory cell to a first programming state S2, and then one or more negative amplitude SET pulses may be used to program the BMC memory cell from first programming state S2 to the second target programming state TS2. Although both techniques result in the BMC memory cell reaching the same desired second target programming state TS2, data retention may differ depending on whether the target programming state is reached from a lower current state (e.g., S2) or a higher current state (e.g., S1).

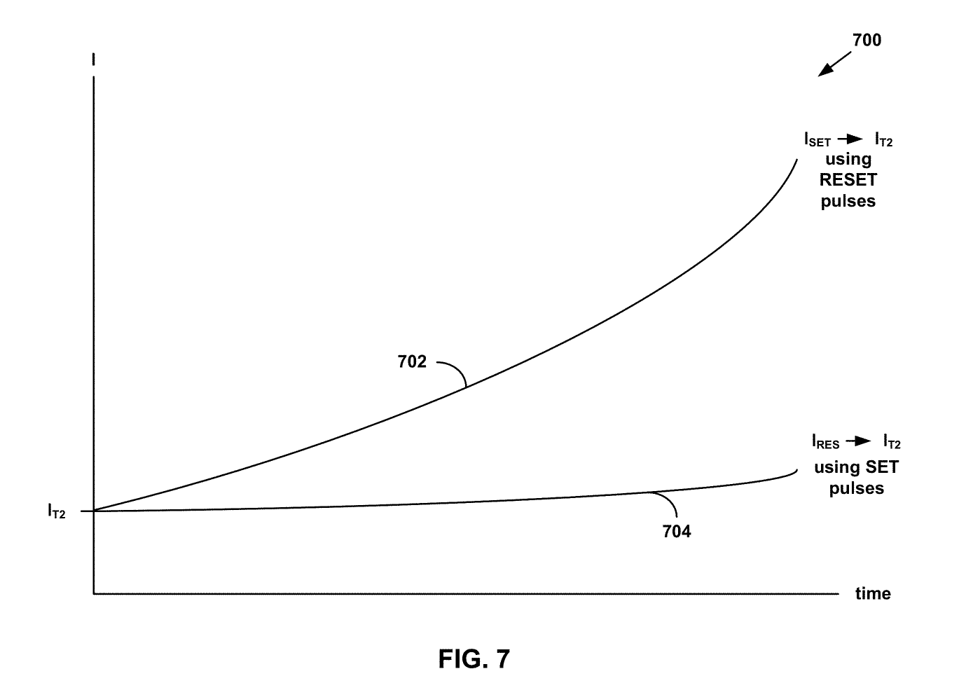

FIG. 7 is a diagram of example current-versus-time characteristics 700 of BMC memory cells, such as memory cells M₁₁₁, M₁₁₂, . . . , M₅₃₆ of FIGS. 3A-3F. Line 702 depicts example read current values for a BMC memory cell after being programmed to second target programming state TS2 from a higher current state (S1 in FIG. 6) using one or more positive amplitude (e.g., RESET) pulses. Line 704 depicts example read current values for a BMC memory cell after being programmed to second target programming state TS2 from a lower current state (e.g., S2 in FIG. 6) using one or more negative amplitude (e.g., SET) pulses.

Without wanting to be bound by any particular theory, it is believed that data retention of BMC memory cells may be “better” or “worse” depending on the manner in which the BMC memory cells are programmed to a desired target programming state. Data retention is determined by how much a programming state changes over time, and “better” data retention means less current change over time. As FIG. 7 illustrates, line 704 exhibits better data retention than line 702 (e.g., the read current varies less in line 704 than in line 702). Without wanting to be bound by any particular theory, it is believed that the data retention properties depend on the particular structure and materials used to fabricate the BMC memory cells.

Without wanting to be bound by any particular theory, it is believed that for some BMC structures and materials, the BMC memory cells may exhibit better data retention if the BMC memory cells are programmed from a lower current state (e.g., S2 in FIG. 6) to any of a number of higher current states (e.g., any of target programming states TS1, TS2, TS3 and TS4 in FIG. 6) using negative amplitude (e.g., SET) programming pulses. For simplicity, such BMC memory cells will be referred to herein as “SET LH BMC memory cells.”

Without wanting to be bound by any particular theory, it is believed that for other BMC structures and materials, the BMC memory cells may exhibit better data retention if the BMC memory cells are programmed from a higher current state (e.g., S1 in FIG. 6) to any of a number of lower current states (e.g., any of target programming states TS1, TS2, TS3 and TS4 in FIG. 6) using positive amplitude (e.g., RESET) programming pulses. For simplicity, such BMC memory cells will be referred to herein as “RESET HL BMC memory cells.”

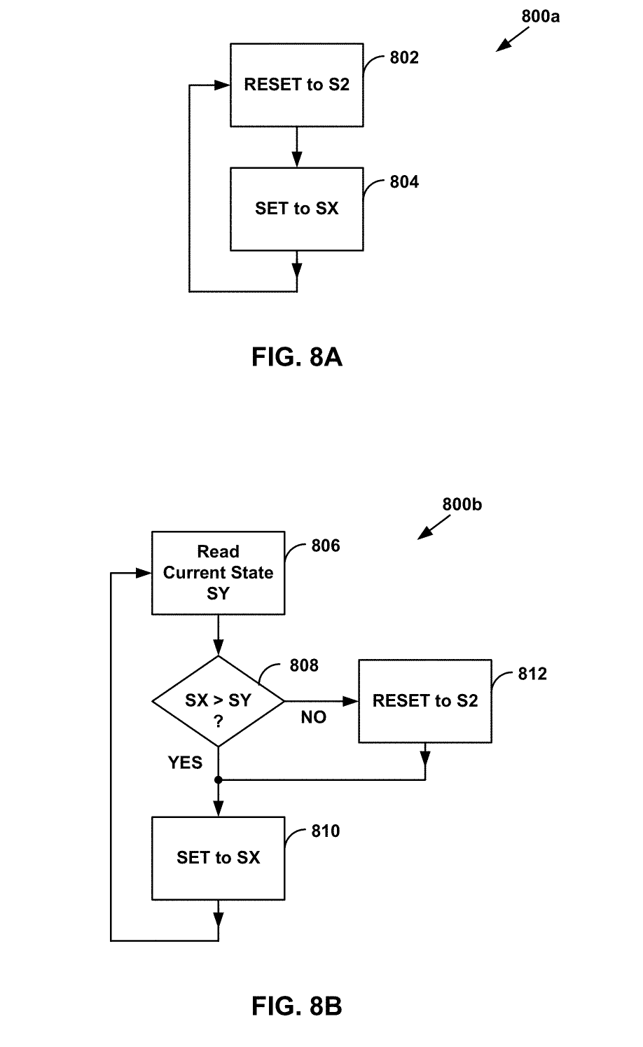

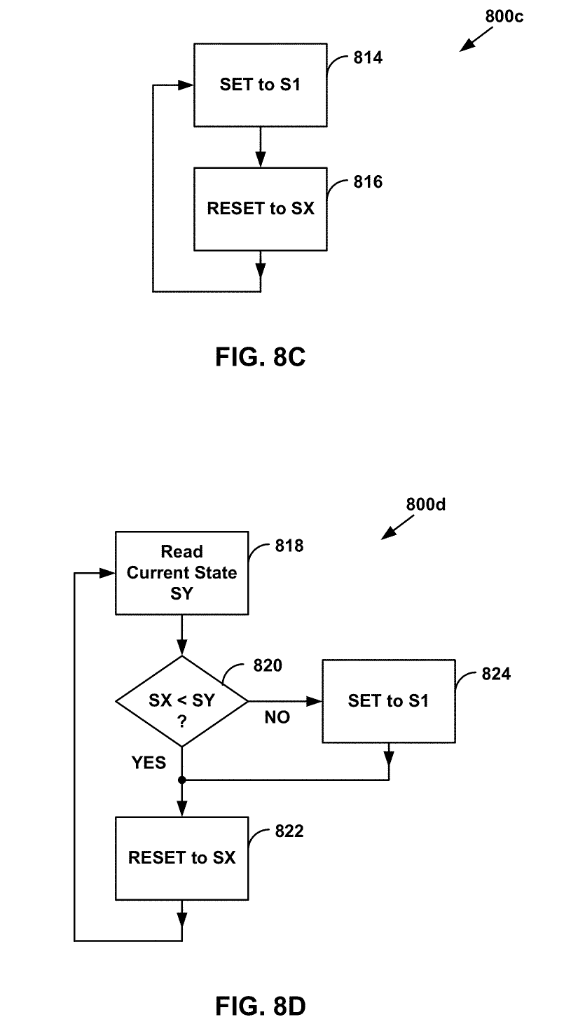

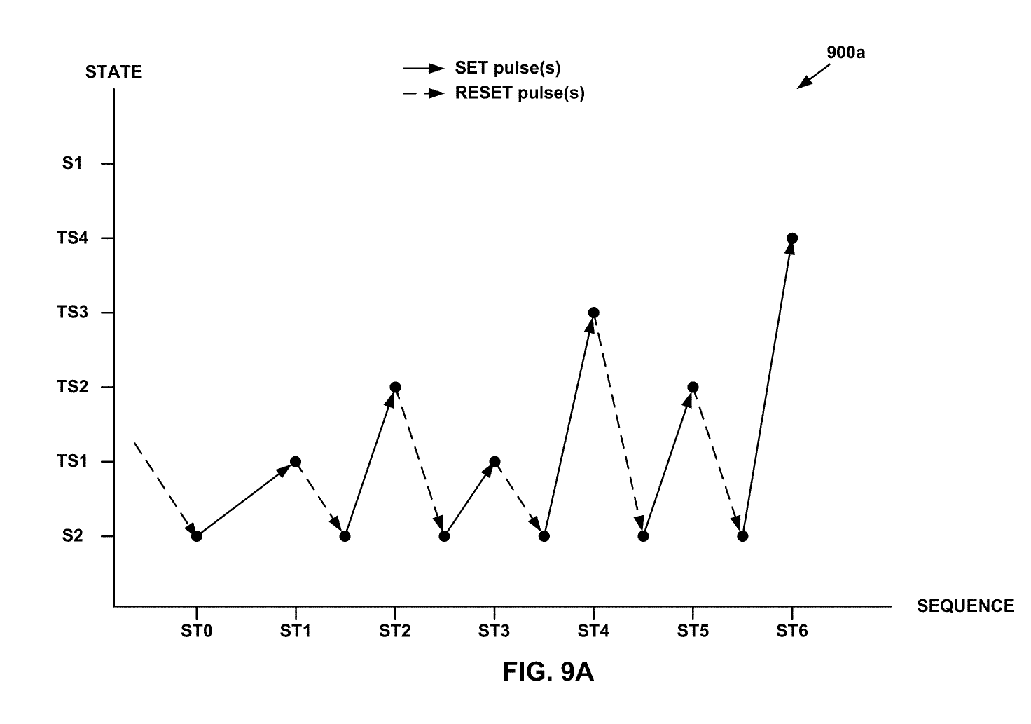

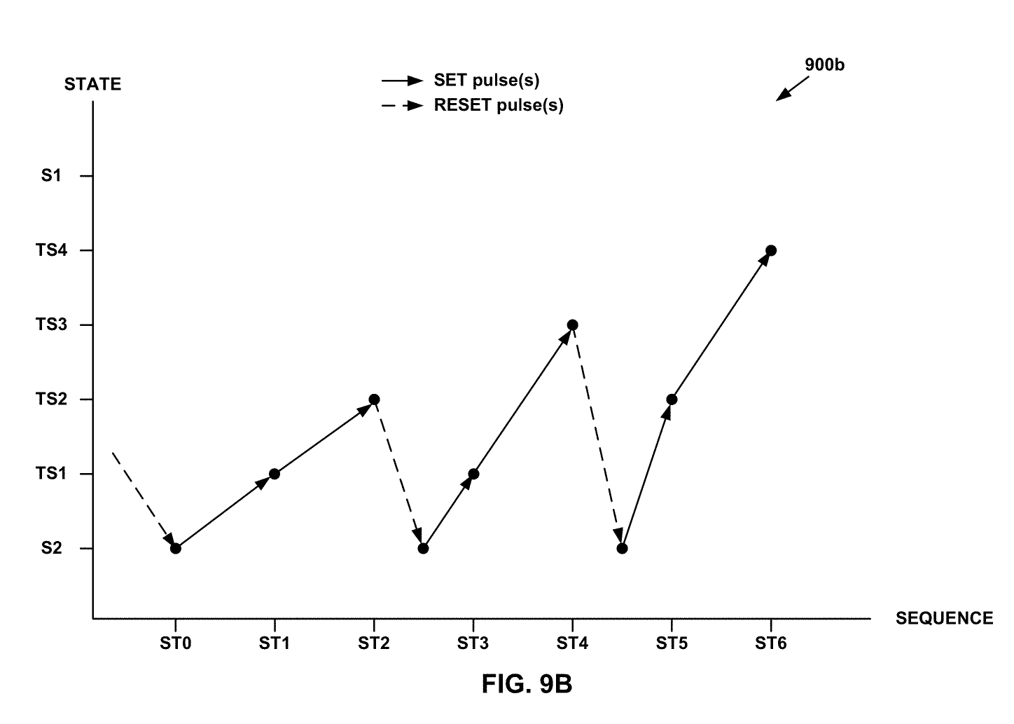

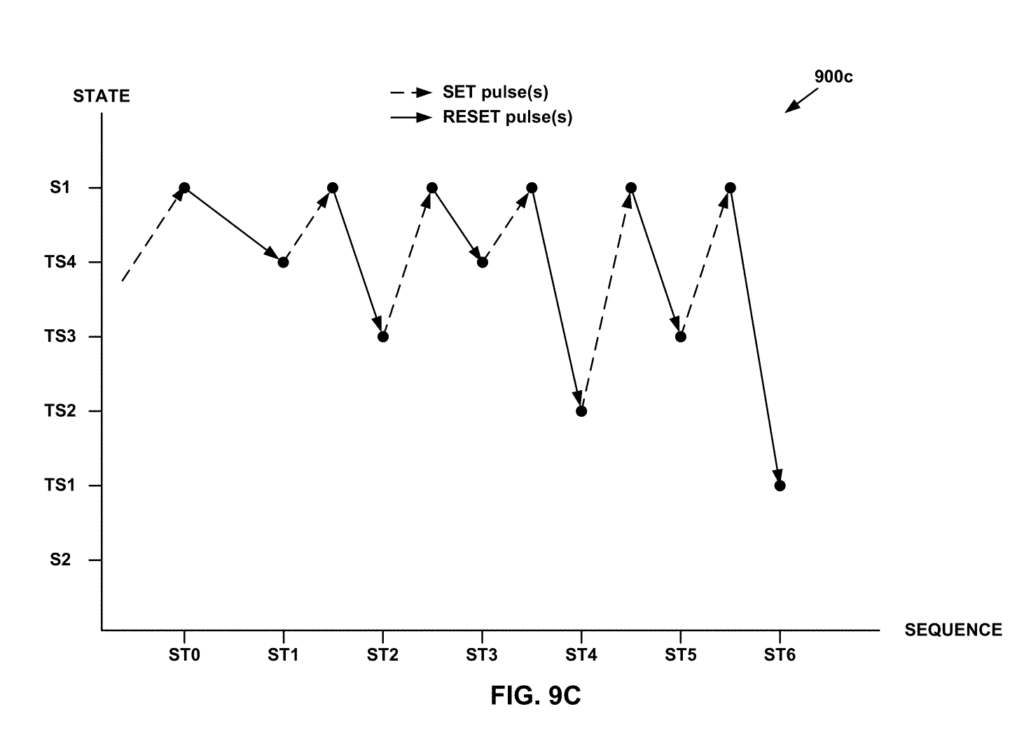

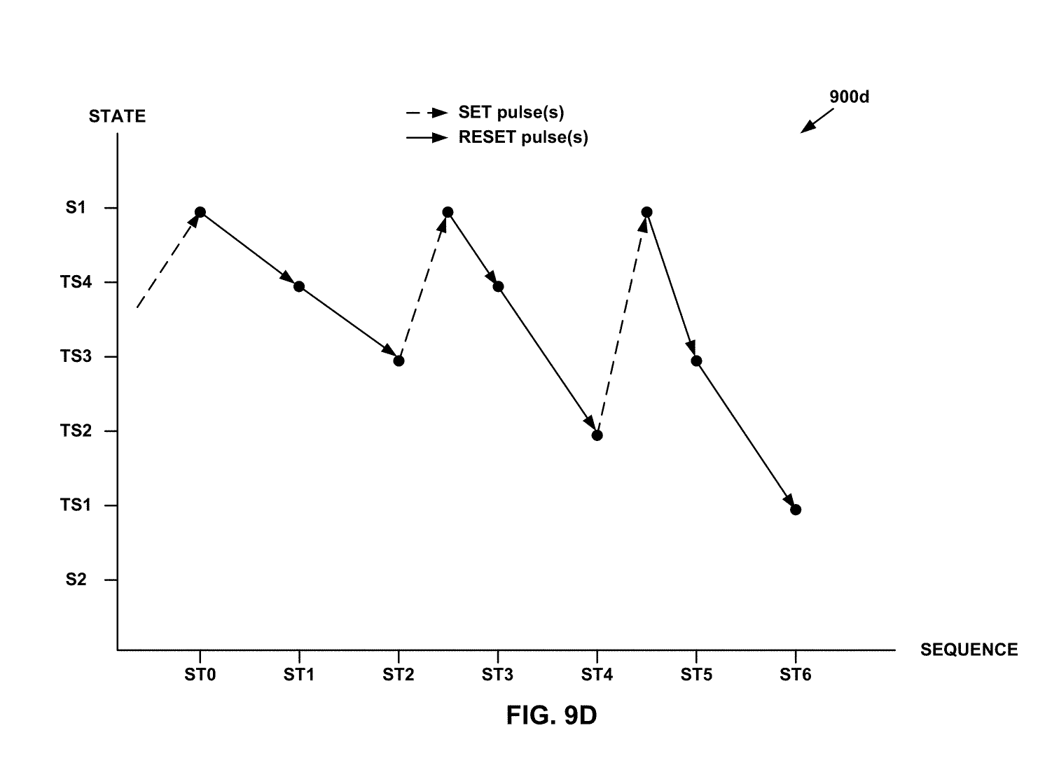

FIGS. 8A-8D are example programming methods for programming BMC memory cells. FIGS. 9A-9D are diagrams of example programming sequences for sequentially programming BMC memory cells using the example programming methods of FIGS. 8A-8D, respectively.

FIG. 8A depicts an embodiment of a method 800a of the disclosed technology for programming BMC memory cells, such as memory cells M₁₁₁, M₁₁₂, . . . , M₅₃₆ of FIGS. 3A-3F. Method 800a may be implemented by a memory controller, such as memory chip controller 104 of FIG. 1A. Method 800a may be used to program a SET LH BMC memory cell from a current programming state SY to a next programming state SX. At step 802, one or more positive amplitude (e.g., RESET) programming pulses are applied to the SET LH BMC memory cell to program the SET LH BMC memory cell to first programming state S2. At step 804, one or more negative amplitude (e.g., SET) programming pulses are applied to the SET LH BMC memory cell to program the SET LH BMC memory cell to next programming state SX.

FIG. 9A is a diagram of an example programming sequence for sequentially programming a SET LH BMC memory cell to target programming states TS1, TS2, TS1, TS3, TS2 and TS4, using the example programming method 800a of FIG. 8A. Prior to sequence step ST0, one or more positive amplitude (e.g., RESET) programming pulses are applied to the SET LH BMC memory cell to program the SET LH BMC memory cell to first programming state S2. Between sequence step ST0 and sequence step ST1, one or more negative amplitude (e.g., SET) programming pulses are applied to the SET LH BMC memory cell to program the SET LH BMC memory cell to first target programming state TS1.

To program the SET LH BMC memory cell to second target programming state TS2, the SET LH BMC memory cell is first programmed to first programming state S2, and then programmed to second target programming state TS2. In particular, between sequence step ST1 and sequence step ST2, one or more positive amplitude (e.g., RESET) programming pulses are applied to the SET LH BMC memory cell to program the SET LH BMC memory cell to first programming state S2, and then one or more negative amplitude (e.g., SET) programming pulses are applied to the SET LH BMC memory cell to program the SET LH BMC memory cell to second target programming state TS2.

To program the SET LH BMC memory cell to first target programming state TS1, the SET LH BMC memory cell is first programmed to first programming state S2, and then programmed to first target programming state TS1. In particular, between sequence step ST2 and sequence step ST3, one or more positive amplitude (e.g., RESET) programming pulses are applied to the SET LH BMC memory cell to program the SET LH BMC memory cell to first programming state S2, and then one or more negative amplitude (e.g., SET) programming pulses are applied to the SET LH BMC memory cell to program the SET LH BMC memory cell to first target programming state TS1.

To program the SET LH BMC memory cell to third target programming state TS3, the SET LH BMC memory cell is first programmed to first programming state S2, and then programmed to third target programming state TS3. In particular, between sequence step ST3 and sequence step ST4, one or more positive amplitude (e.g., RESET) programming pulses are applied to the SET LH BMC memory cell to program the SET LH BMC memory cell to first programming state S2, and then one or more negative amplitude (e.g., SET) programming pulses are applied to the SET LH BMC memory cell to program the SET LH BMC memory cell to third target programming state TS3.

To program the SET LH BMC memory cell to second target programming state TS2, the SET LH BMC memory cell is first programmed to first programming state S2, and then programmed to second target programming state TS2. In particular, between sequence step ST4 and sequence step ST5, one or more positive amplitude (e.g., RESET) programming pulses are applied to the SET LH BMC memory cell to program the SET LH BMC memory cell to first programming state S2, and then one or more negative amplitude (e.g., SET) programming pulses are applied to the SET LH BMC memory cell to program the SET LH BMC memory cell to second target programming state TS2.

To program the SET LH BMC memory cell to fourth target programming state TS4, the SET LH BMC memory cell is first programmed to first programming state S2, and then programmed to fourth target programming state TS4. In particular, between sequence step ST5 and sequence step ST6, one or more positive amplitude (e.g., RESET) programming pulses are applied to the SET LH BMC memory cell to program the SET LH BMC memory cell to first programming state S2, and then one or more negative amplitude (e.g., SET) programming pulses are applied to the SET LH BMC memory cell to program the SET LH BMC memory cell to fourth target programming state TS4.

FIG. 8B depicts an embodiment of a method 800b of the disclosed technology for programming BMC memory cells, such as memory cells M₁₁₁, M₁₁₂, . . . , M₅₃₆ of FIGS. 3A-3F. Method 800b may be implemented by a memory controller, such as memory chip controller 104 of FIG. 1A. Method 800b may be used to program a SET LH BMC memory cell from a current programming state SY to a next programming state SX.

At step 806, the current programming state SY of SET LH BMC memory cell is determined (e.g., using a read operation). At step 808, a determination is made whether the next programming state SX is a higher current state than the current programming state SY. If the next programming state SX is a higher current state than the current programming state SY, at step 810 one or more negative amplitude (e.g., SET) programming pulses are applied to the SET LH BMC memory cell to program the SET LH BMC memory cell to the next programming state SX.

If, however, the next programming state SX is not a higher current state than the current programming state SY, at step 812 one or more positive amplitude (e.g., RESET) programming pulses are applied to the SET LH BMC memory cell to program the SET LH BMC memory cell to first programming state S2. Then, at step 810, one or more negative amplitude (e.g., SET) programming pulses are applied to the SET LH BMC memory cell to program the SET LH BMC memory cell to the next programming state SX.

FIG. 9B is a diagram of an example programming sequence for sequentially programming a SET LH BMC memory cell to target programming states TS1, TS2, TS1, TS3, TS2 and TS4, using the example programming method 800b of FIG. 8B. Prior to sequence step ST0, one or more positive amplitude (e.g., RESET) programming pulses are applied to the SET LH BMC memory cell to program the SET LH BMC memory cell to first programming state S2.

To program the SET LH BMC memory cell to first target programming state TS1, a read operation is used to determine the current state of the SET LH BMC memory cell, and then a determination is made whether the next programming state TS1 is a higher current state than the current programming state S2. Because the next programming state TS1 is a higher current state than the current programming state S2, negative amplitude (e.g., SET) programming pulses are used to program the SET LH BMC memory cell to first target programming state TS1. Accordingly, between sequence step ST0 and sequence step ST1, one or more negative amplitude (e.g., SET) programming pulses are applied to the SET LH BMC memory cell to program the SET LH BMC memory cell to first target programming state TS1.

To program the SET LH BMC memory cell to second target programming state TS2, a read operation is used to determine the current state of the SET LH BMC memory cell, and then a determination is made whether the next programming state TS2 is a higher current state than the current programming state TS1. Because the next programming state TS2 is a higher current state than the current programming state TS1, negative amplitude (e.g., SET) programming pulses are used to program the SET LH BMC memory cell to second target programming state TS2. Accordingly, between sequence step ST1 and sequence step ST2, one or more negative amplitude (e.g., SET) programming pulses are applied to the SET LH BMC memory cell to program the SET LH BMC memory cell to second target programming state TS2.

To program the SET LH BMC memory cell to first target programming state TS1, a read operation is used to determine the current state of the SET LH BMC memory cell, and then a determination is made whether the next programming state TS1 is a higher current state than the current programming state TS2. Because the next programming state TS1 is not a higher current state than the current programming state TS2, positive amplitude (e.g., RESET) programming pulses are used to program the SET LH BMC memory cell to first programming state S2, and then negative amplitude (e.g., SET) programming pulses are used to program the SET LH BMC memory cell to first target programming state TS1.

Accordingly, between sequence step ST2 and sequence step ST3, one or more positive amplitude (e.g., RESET) programming pulses are applied to the SET LH BMC memory cell to program the SET LH BMC memory cell to first programming state S2, and then one or more negative amplitude (e.g., SET) programming pulses are applied to the SET LH BMC memory cell to program the SET LH BMC memory cell to first target programming state TS1.

To program the SET LH BMC memory cell to third target programming state TS3, a read operation is used to determine the current state of the SET LH BMC memory cell, and then a determination is made whether the next programming state TS3 is a higher current state than the current programming state TS1. Because the next programming state TS3 is a higher current state than the current programming state TS1, negative amplitude (e.g., SET) programming pulses are used to program the SET LH BMC memory cell to third target programming state TS3. Accordingly, between sequence step ST3 and sequence step ST4, one or more negative amplitude (e.g., SET) programming pulses are applied to the SET LH BMC memory cell to program the SET LH BMC memory cell to third target programming state TS3.

To program the SET LH BMC memory cell to second target programming state TS2, a read operation is used to determine the current state of the SET LH BMC memory cell, and then a determination is made whether the next programming state TS2 is a higher current state than the current programming state TS3. Because the next programming state TS2 is not a higher current state than the current programming state TS3, positive amplitude (e.g., RESET) programming pulses are used to program the SET LH BMC memory cell to first programming state S2, and then negative amplitude (e.g., SET) programming pulses are used to program the SET LH BMC memory cell to second target programming state TS2.

Accordingly, between sequence step ST4 and sequence step ST5, one or more positive amplitude (e.g., RESET) programming pulses are applied to the SET LH BMC memory cell to program the SET LH BMC memory cell to first programming state S2, and then one or more negative amplitude (e.g., SET) programming pulses are applied to the SET LH BMC memory cell to program the SET LH BMC memory cell to second target programming state TS2.

To program the SET LH BMC memory cell to fourth target programming state TS4, a read operation is used to determine the current state of the SET LH BMC memory cell, and then a determination is made whether the next programming state TS4 is a higher current state than the current programming state TS2. Because the next programming state TS4 is a higher current state than the current programming state TS2, negative amplitude (e.g., SET) programming pulses are used to program the SET LH BMC memory cell to fourth target programming state TS4. Accordingly, between sequence step ST5 and sequence step ST6, one or more negative amplitude (e.g., SET) programming pulses are applied to the SET LH BMC memory cell to program the SET LH BMC memory cell to fourth target programming state TS4.

FIG. 8C depicts an embodiment of a method 800c of the disclosed technology for programming BMC memory cells, such as memory cells M₁₁₁, M₁₁₂, . . . , M₅₃₆ of FIGS. 3A-3F. Method 800c may be implemented by a memory controller, such as memory chip controller 104 of FIG. 1A. Method 800c may be used to program a RESET HL BMC memory cell from a current programming state SY to a next programming state SX. At step 814, one or more negative amplitude (e.g., SET) programming pulses are applied to the RESET HL BMC memory cell to program the RESET HL BMC memory cell to first programming state S1. At step 816, one or more positive amplitude (e.g., RESET) programming pulses are applied to the RESET HL BMC memory cell to program the RESET HL BMC memory cell to next programming state SX.

FIG. 9C is a diagram of an example programming sequence for sequentially programming a RESET HL BMC memory cell to target programming states TS4, TS3, TS4, TS2, TS3 and TS1, using the example programming method 800c of FIG. 8C. Prior to sequence step ST0, one or more negative amplitude (e.g., SET) programming pulses are applied to the RESET HL BMC memory cell to program the RESET HL BMC memory cell to first programming state S1. Between sequence step ST0 and sequence step ST1, one or more positive amplitude (e.g., RESET) programming pulses are applied to the RESET HL BMC memory cell to program the RESET HL BMC memory cell to fourth target programming state TS4.

To program the RESET HL BMC memory cell to third target programming state TS3, the RESET HL BMC memory cell is first programmed to first programming state S1, and then programmed to third target programming state TS3. In particular, between sequence step ST1 and sequence step ST2, one or more negative amplitude (e.g., SET) programming pulses are applied to the RESET HL BMC memory cell to program the RESET HL BMC memory cell to first programming state S1, and then one or more positive amplitude (e.g., RESET) programming pulses are applied to the RESET HL BMC memory cell to program the RESET HL BMC memory cell to third target programming state TS3.

To program the RESET HL BMC memory cell to fourth target programming state TS4, the RESET HL BMC memory cell is first programmed to first programming state S1, and then programmed to fourth target programming state TS4. In particular, between sequence step ST2 and sequence step ST3, one or more negative amplitude (e.g., SET) programming pulses are applied to the RESET HL BMC memory cell to program the RESET HL BMC memory cell to first programming state S1, and then one or more positive amplitude (e.g., RESET) programming pulses are applied to the RESET HL BMC memory cell to program the RESET HL BMC memory cell to fourth target programming state TS4.

To program the RESET HL BMC memory cell to second target programming state TS2, the RESET HL BMC memory cell is first programmed to first programming state S1, and then programmed to second target programming state TS2. In particular, between sequence step ST3 and sequence step ST4, one or more negative amplitude (e.g., SET) programming pulses are applied to the RESET HL BMC memory cell to program the RESET HL BMC memory cell to first programming state S1, and then one or more positive amplitude (e.g., RESET) programming pulses are applied to the RESET HL BMC memory cell to program the RESET HL BMC memory cell to second target programming state TS2.

To program the RESET HL BMC memory cell to third target programming state TS3, the RESET HL BMC memory cell is first programmed to first programming state S1, and then programmed to third target programming state TS3. In particular, between sequence step ST4 and sequence step ST5, one or more negative amplitude (e.g., SET) programming pulses are applied to the RESET HL BMC memory cell to program the RESET HL BMC memory cell to first programming state S1, and then one or more positive amplitude (e.g., RESET) programming pulses are applied to the RESET HL BMC memory cell to program the RESET HL BMC memory cell to third target programming state TS3.

To program the RESET HL BMC memory cell to first target programming state TS1, the RESET HL BMC memory cell is first programmed to first programming state S1, and then programmed to first target programming state TS1. In particular, between sequence step ST5 and sequence step ST6, one or more negative amplitude (e.g., SET) programming pulses are applied to the RESET HL BMC memory cell to program the RESET HL BMC memory cell to first programming state S1, and then one or more positive amplitude (e.g., RESET) programming pulses are applied to the RESET HL BMC memory cell to program the RESET HL BMC memory cell to first target programming state TS1.

FIG. 8D depicts an embodiment of a method 800d of the disclosed technology for programming BMC memory cells, such as memory cells M₁₁₁, M₁₁₂, . . . , M₅₃₆ of FIGS. 3A-3F. Method 800d may be implemented by a memory controller, such as memory chip controller 104 of FIG. 1A. Method 800d may be used to program a RESET HL BMC memory cell from a current programming state SY to a next programming state SX.

At step 818, the current programming state SY of RESET HL BMC memory cell is determined (e.g., using a read operation). At step 820, a determination is made whether the next programming state SX is a lower current state than the current programming state SY. If the next programming state SX is a lower current state than the current programming state SY, at step 822 one or more positive amplitude (e.g., RESET) programming pulses are applied to the RESET HL BMC memory cell to program the RESET HL BMC memory cell to the next programming state SX.

If, however, the next programming state SX is not a lower current state than the current programming state SY, at step 824 one or more negative amplitude (e.g., SET) programming pulses are applied to the RESET HL BMC memory cell to program the RESET HL BMC memory cell to first programming state S1. Then, at step 822, one or more positive amplitude (e.g., RESET) programming pulses are applied to the RESET HL BMC memory cell to program the RESET HL BMC memory cell to the next programming state SX.

FIG. 9D is a diagram of an example programming sequence for sequentially programming a RESET HL BMC memory cell to target programming states TS4, TS3, TS4, TS2, TS3 and TS1, using the example programming method 800d of FIG. 8D. Prior to sequence step ST0, one or more negative amplitude (e.g., SET) programming pulses are applied to the RESET HL BMC memory cell to program the RESET HL BMC memory cell to first programming state S1.

To program the RESET HL BMC memory cell to fourth target programming state TS4, a read operation is used to determine the current state of the RESET HL BMC memory cell, and then a determination is made whether the next programming state TS4 is a lower current state than the current programming state S1. Because the next programming state TS4 is a lower current state than the current programming state S1, positive amplitude (e.g., RESET) programming pulses are used to program the RESET HL BMC memory cell to fourth target programming state TS4. Accordingly, between sequence step ST0 and sequence step ST1, one or more positive amplitude (e.g., RESET) programming pulses are applied to the RESET HL BMC memory cell to program the RESET HL BMC memory cell to fourth target programming state TS4.

To program the RESET HL BMC memory cell to third target programming state TS3, a read operation is used to determine the current state of the RESET HL BMC memory cell, and then a determination is made whether the next programming state TS1 is a lower current state than the current programming state TS4. Because the next programming state TS3 is a lower current state than the current programming state TS4, positive amplitude (e.g., RESET) programming pulses are used to program the RESET HL BMC memory cell to third target programming state TS3. Accordingly, between sequence step ST1 and sequence step ST2, one or more positive amplitude (e.g., RESET) programming pulses are applied to the RESET HL BMC memory cell to program the RESET HL BMC memory cell to third target programming state TS3.

To program the RESET HL BMC memory cell to fourth target programming state TS4, a read operation is used to determine the current state of the RESET HL BMC memory cell, and then a determination is made whether the next programming state TS4 is a lower current state than the current programming state TS3. Because the next programming state TS4 is not a lower current state than the current programming state TS3, negative amplitude (e.g., SET) programming pulses are used to program the RESET HL BMC memory cell to first programming state S1, and then positive amplitude (e.g., RESET) programming pulses are used to program the RESET HL BMC memory cell to fourth target programming state TS4.

Accordingly, between sequence step ST2 and sequence step ST3, one or more negative amplitude (e.g., SET) programming pulses are applied to the RESET HL BMC memory cell to program the RESET HL BMC memory cell to first programming state S1, and then one or more positive amplitude (e.g., RESET) programming pulses are applied to the RESET HL BMC memory cell to program the RESET HL BMC memory cell to fourth target programming state TS4.

To program the RESET HL BMC memory cell to second target programming state TS2, a read operation is used to determine the current state of the RESET HL BMC memory cell, and then a determination is made whether the next programming state TS2 is a lower current state than the current programming state TS4. Because the next programming state TS2 is a lower current state than the current programming state TS4, positive amplitude (e.g., RESET) programming pulses are used to program the RESET HL BMC memory cell to second target programming state TS2. Accordingly, between sequence step ST3 and sequence step ST4, one or more positive amplitude (e.g., RESET) programming pulses are applied to the RESET HL BMC memory cell to program the RESET HL BMC memory cell to second target programming state TS2.

To program the RESET HL BMC memory cell to third target programming state TS3, a read operation is used to determine the current state of the RESET HL BMC memory cell, and then a determination is made whether the next programming state TS3 is a lower current state than the current programming state TS2. Because the next programming state TS3 is not a lower current state than the current programming state TS2, negative amplitude (e.g., SET) programming pulses are used to program the RESET HL BMC memory cell to first programming state S1, and then positive amplitude (e.g., RESET) programming pulses are used to program the RESET HL BMC memory cell to third target programming state TS3.

Accordingly, between sequence step ST4 and sequence step ST5, one or more negative amplitude (e.g., SET) programming pulses are applied to the RESET HL BMC memory cell to program the RESET HL BMC memory cell to first programming state S1, and then one or more positive amplitude (e.g., RESET) programming pulses are applied to the RESET HL BMC memory cell to program the RESET HL BMC memory cell to third target programming state TS3.

To program the RESET HL BMC memory cell to first target programming state TS1, a read operation is used to determine the current state of the RESET HL BMC memory cell, and then a determination is made whether the next programming state TS1 is a lower current state than the current programming state TS3. Because the next programming state TS1 is a lower current state than the current programming state TS3, positive amplitude (e.g., RESET) programming pulses are used to program the RESET HL BMC memory cell to first target programming state TS1. Accordingly, between sequence step ST5 and sequence step ST6, one or more positive amplitude (e.g., RESET) programming pulses are applied to the RESET HL BMC memory cell to program the RESET HL BMC memory cell to first target programming state TS1.

As described above, without wanting to be bound by any particular theory it is believed that data retention of BMC memory cells vary depending on the manner in which the BMC memory cells are programmed to a desired target programming state. In addition, without wanting to be bound by any particular theory it is believed that the direction or trajectory for programming a given state (e.g., from a lower current state to a higher current state, or from a higher current state to a lower current state) may affect a magnitude and a direction of relaxation.

In an embodiment, a BMC memory cell is programmed to a first programming state from a first intermediate programming state using one or more programming pulses having a first polarity, and is programmed to a second programming state from a second intermediate programming state using one or more programming pulses having a second polarity opposite the first polarity.

In an embodiment, the first programming state is a lower current state than the second programming state, the first intermediate programming state is a lower current state than the first programming state, and the second intermediate programming state is a higher current state than the second programming state. The first intermediate programming state and the second intermediate programming state are “overshoot” programming states.

To program the BMC memory cell to the first programming state, the BMC memory cell is first programmed to the first intermediate programming state (the “overshoot” lower current state) using programming pulses having the first polarity, and then programmed to the first programming state using programming pulses having the second polarity opposite the first polarity.

To program the BMC memory cell to the second programming state, the BMC memory cell is first programmed to the second intermediate programming state (the “overshoot” higher current state) using programming pulses having the second polarity, and then programmed to the second programming state using programming pulses having the first polarity.

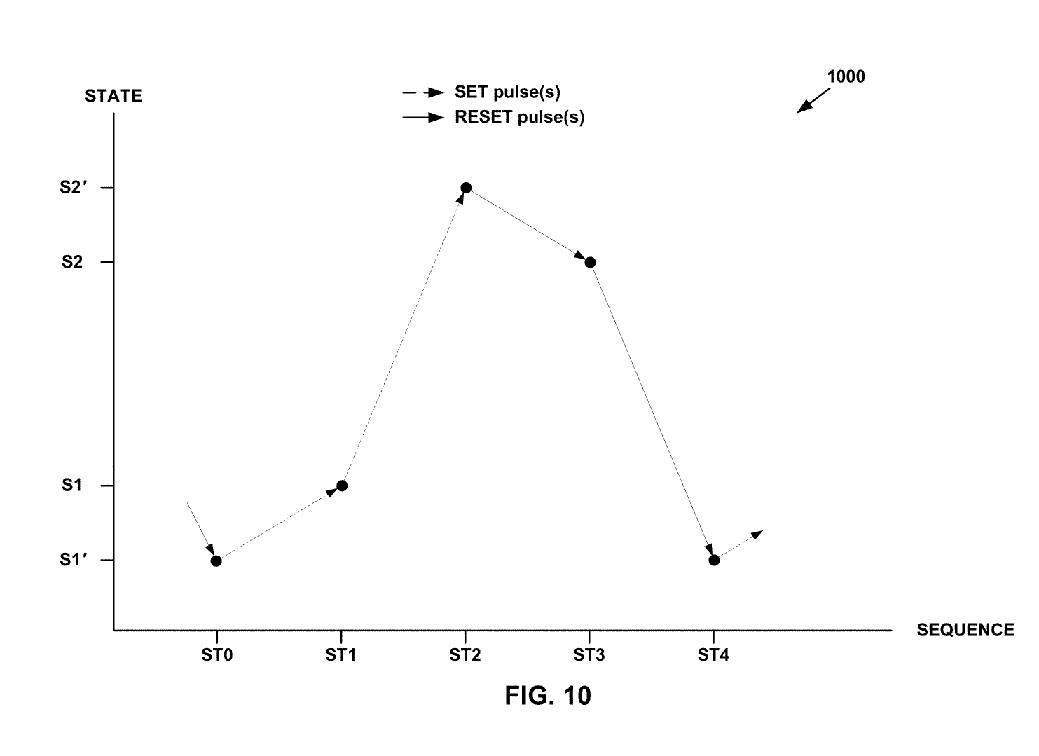

FIG. 10 an example programming sequence 1000 for programming a BMC memory cell to a first programming state S1 from a first intermediate programming state S1′, and programming the BMC memory cell to a second programming state S2 from a second intermediate programming state S2′. First intermediate programming state S1′ is an “overshoot” lower current state, and second intermediate programming state S2′ is an “overshoot” higher current state.

Beginning at sequence step ST0, the BMC memory cell is in first intermediate programming state S1′. Between sequence step ST0 and sequence step ST1, one or more programming pulses having a first polarity (e.g., negative polarity SET pulses) are applied to the BMC memory cell to program the BMC memory cell from the first intermediate programming state S1′ to the first programming state S1.

Between sequence step ST1 and sequence step ST2, one or more programming pulses having the first polarity (e.g., negative polarity SET pulses) are applied to the BMC memory cell to program the BMC memory cell from the first programming state S1 to the second intermediate programming state S2′.

Between sequence step ST2 and sequence step ST3, one or more programming pulses having a second polarity (e.g., positive polarity RESET pulses) are applied to the BMC memory cell to program the BMC memory cell from the second intermediate programming state S2′ to the second programming state S2.

Between sequence step ST3 and sequence step ST4, one or more programming pulses having the second polarity (e.g., positive polarity RESET pulses) are applied to the BMC memory cell to program the BMC memory cell from the second programming state S2 to the first intermediate programming state S1′.

Without wanting to be bound by any particular theory, it is believed that the magnitude and direction of relaxation of the first programming state S1 is approximately equal to the magnitude and direction of relaxation of the second programming state S2. As a result, without wanting to be bound by any particular theory, it is believed that example programming sequence 1000 will result in improved read margin between the first programming state S1 and the second programming state S2.

Thus, as described above, one embodiment of the disclosed technology includes a memory device that includes a memory controller coupled to a memory cell including a barrier modulated switching structure. The memory controller is adapted to program the memory cell to a first programming state, and program the memory cell to one of a plurality of target programming states from the first programming state.

One embodiment of the disclosed technology includes a method including applying one or more programming pulses having a first polarity to a memory cell including a barrier modulated switching structure to program the memory cell to a first programming state, and applying one or more programming pulses having a second polarity to the memory cell to program the memory cell from the first programming state to a first target programming state, wherein the second polarity is opposite the first polarity.

One embodiment of the disclosed technology includes a memory device that includes a memory controller coupled to a memory cell including a barrier modulated switching structure. The memory controller is adapted to apply one or more programming pulses having a first polarity to the memory cell to program the memory cell from a first intermediate programming state to a first programming state, apply one or more programming pulses having the first polarity to the memory cell to program the memory cell from the first programming state to a second intermediate programming state, apply one or more programming pulses having a second polarity to the memory cell to program the memory cell from the second intermediate programming state to a second programming state, wherein the second polarity is opposite the first polarity, and apply one or more programming pulses having the second polarity to the memory cell to program the memory cell from the second programming state to the first intermediate programming state.

For purposes of this document, each process associated with the disclosed technology may be performed continuously and by one or more computing devices. Each step in a process may be performed by the same or different computing devices as those used in other steps, and each step need not necessarily be performed by a single computing device.

For purposes of this document, reference in the specification to “an embodiment,” “one embodiment,” “some embodiments,” or “another embodiment” may be used to described different embodiments and do not necessarily refer to the same embodiment.

For purposes of this document, a connection can be a direct connection or an indirect connection (e.g., via another part).

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A memory device comprising:
a memory controller coupled to a memory cell comprising a barrier modulated switching structure, wherein the memory controller is adapted to:
program the memory cell to a first programming state; and
program the memory cell to one of a plurality of target programming states from the first programming state.

2. The memory device of claim 1, wherein the first programming state comprises a first read current, and the plurality of target programming states comprise a corresponding plurality of target read currents.

3. The memory device of claim 2, wherein each of the plurality of target read currents is greater than the first read current.

4. The memory device of claim 2, wherein each of the plurality of target read currents is less than the first read current.

5. The memory device of claim 1, wherein the plurality of target programming states comprise three or more target programming states.

6. The memory device of claim 1, wherein the memory controller is further adapted to:
apply one or more programming pulses having a first polarity to the memory cell to program the memory cell to the first programming state; and
apply one or more programming pulses having a second polarity to the memory cell to program the memory cell to one of the plurality of target programming states, wherein the second polarity is opposite the first polarity.

7. The memory device of claim 1, wherein the memory cell comprises a reversible resistance-switching material disposed between a first conductor and a second conductor, wherein the reversible resistance-switching material comprises a semiconductor material layer adjacent a conductive oxide material layer.

8. The memory device of claim 7, wherein:
the semiconductor material layer comprises one or more of carbon, germanium, silicon, tantalum nitride, tantalum silicon nitride; and
the conductive oxide material layer comprises one or more of aluminum-doped zinc oxide, aluminum-doped zirconium oxide, cerium oxide, indium tin oxide, niobium-doped strontium titanate, praseodymium calcium manganese oxide, titanium oxide, tungsten oxide, and zinc oxide.

9. A method comprising:
applying one or more programming pulses having a first polarity to a memory cell comprising a barrier modulated switching structure to program the memory cell to a first programming state; and
applying one or more programming pulses having a second polarity to the memory cell to program the memory cell from the first programming state to a first target programming state, wherein the second polarity is opposite the first polarity.

10. The method of claim 9, further comprising:
applying one or more programming pulses having the first polarity to the memory cell to program the memory cell from the first target programming state to the first programming state; and
applying one or more programming pulses having the second polarity to the memory cell to program the memory cell from the first programming state to a second target programming state.

11. The method of claim 9, further comprising:
reading the memory cell to determine a current programming state of the memory cell;
determining that a second target programming state is greater than the current programming state; and
applying one or more programming pulses having the second polarity to the memory cell to program the memory cell from the current programming state to the second target programming state.

12. The method of claim 9, further comprising:
reading the memory cell to determine a current programming state of the memory cell;
determining that a second target programming state is less than the current programming state;
applying one or more programming pulses having the first polarity to the memory cell to program the memory cell from the current programming state to the first programming state; and
applying one or more programming pulses having the second polarity to the memory cell to program the memory cell from the first programming state to the second target programming state.

13. The method of claim 9, further comprising:
reading the memory cell to determine a current programming state of the memory cell;
determining that a second target programming state is less than the current programming state; and
applying one or more programming pulses having the second polarity to the memory cell to program the memory cell from the current programming state to the second target programming state.

14. The method of claim 9, further comprising:
reading the memory cell to determine a current programming state of the memory cell;
determining that a second target programming state is greater than the current programming state;
applying one or more programming pulses having the first polarity to the memory cell to program the memory cell from the current programming state to the first programming state; and
applying one or more programming pulses having the second polarity to the memory cell to program the memory cell from the first programming state to the second target programming state.

15. The method of claim 9, wherein the memory cell comprises a reversible resistance-switching material disposed between a first conductor and a second conductor, wherein the reversible resistance-switching material comprises a semiconductor material layer adjacent a conductive oxide material layer.

16. The method of claim 15, wherein:
the semiconductor material layer comprises one or more of carbon, germanium, silicon, tantalum nitride, tantalum silicon nitride; and
the conductive oxide material layer comprises one or more of aluminum-doped zinc oxide, aluminum-doped zirconium oxide, cerium oxide, indium tin oxide, niobium-doped strontium titanate, praseodymium calcium manganese oxide, titanium oxide, tungsten oxide, and zinc oxide.

17. A memory device comprising:
a memory controller coupled to a memory cell comprising a barrier modulated switching structure, wherein the memory controller is adapted to:
apply one or more programming pulses having a first polarity to the memory cell to program the memory cell from a first intermediate programming state to a first programming state;
apply one or more programming pulses having the first polarity to the memory cell to program the memory cell from the first programming state to a second intermediate programming state;
apply one or more programming pulses having a second polarity to the memory cell to program the memory cell from the second intermediate programming state to a second programming state, wherein the second polarity is opposite the first polarity; and
apply one or more programming pulses having the second polarity to the memory cell to program the memory cell from the second programming state to the first intermediate programming state.

18. The memory device of claim 17, wherein the first programming state is more conductive than the first intermediate programming state, and the second programming state is less conductive than the second intermediate programming state.

19. The memory device of claim 17, wherein the first programming state is less conductive than the first intermediate programming state, and the second programming state is more conductive than the second intermediate programming state.

20. The memory device of claim 17, wherein the memory cell comprises a reversible resistance-switching material disposed between a first conductor and a second conductor, wherein the reversible resistance-switching material comprises a semiconductor material layer adjacent a conductive oxide material layer.
